(19) United States
(12) Patent Application Publication
(10) Pub. No.: US 2007/0158731 A1
(43) Pub. Date: Jul. 12, 2007

(54) Memory Devices Employing Ferroelectric Layer as Information Storage Elements and Methods of Fabricating the Same

(75) Inventors: Byoung-Jae Bae, Gyeonggi-do (KR); Byung-Gil Jeon, Gyeonggi-do (KR); Heung-Jin Joo, Gyeonggi-do (KR); Dong-Chul Yoo, Gyeonggi-do (KR); Sang-Don Nam, Seoul (KR)

Correspondence Address: MYERS BIGEL SIBLEY & SAJOVEC, PO BOX 37428, RALEIGH, NC, 27627, US

(73) Assignee: Samsung Electronics Co., Ltd.

(21) Appl. No.: 11/620,225

(22) Filed: Jan. 5, 2007

(30) Foreign Application Priority Data
Jan. 6, 2006 (KR) 2006-1896

(51) Int. Cl. H01L 29/76

(52) U.S. Cl. 257/314

(57) ABSTRACT

A memory device includes one or more layers of parallel strings of ferroelectric gate transistors on a substrate, each layer of parallel strings including a plurality of parallel line-shaped active regions and a plurality of word lines extending in parallel transversely across the active regions and disposed on ferroelectric patterns on the active regions. A string select gate line may extend transversely across the active regions in parallel with the word lines. A ground select gate line may extend transversely across the active regions in parallel with the word lines.

### CROSS-REFERENCE TO RELATED APPLICATION

This application claims the benefit of Korean Patent Application No. 10-2006-1896, filed on Jan. 6, 2006, the disclosure of which is hereby incorporated herein by reference in its entirety.

### BACKGROUND OF THE INVENTION

1. Field of the Invention

The present invention relates to semiconductor devices and methods of fabricating the same, and more particularly, to flash memory devices and methods of fabricating the same.

2. Description of the Related Art

In order to meet the need of the rapidly developing information-oriented society for an information storage element that is miniaturized, consumes minimal power, and is convenient to use, research has been conducted into non-volatile ferroelectric memory devices capable of storing information even when power is not supplied to an information storage element. Nonvolatile memory cells using ferroelectric substances may be classified into Destructive Readout (DRO) type and Non Destructive Readout (NDRO) type.

A typical DRO type memory cell is composed of a transistor, which acts as a switch for delivering information, and a ferroelectric capacitor, which acts as an information storage element. Polarization occurs in a ferroelectric substance forming the ferroelectric capacitor due to a voltage applied through the transistor, and this polarization is maintained so that information is stored even when the voltage is removed. The polarization direction is first reversed back to a positive saturation polarization state by a read signal when a negative remnant polarization state is stored in the ferroelectric substance by applying a voltage to the capacitor in a direction causing positive saturation polarization to occur, regardless of the polarization direction of the ferroelectric substance, in order to read the stored information. Accordingly, when the negative polarization state is indicated as “1” to store information, in order to read the information “1”, the negative remnant polarization is lost and the state is converted to the positive saturation polarization state. The result is the positive remnant polarization state and erasure of the previously stored information “1”. Accordingly, the original signal “1” may be restored when the negative polarization is recreated. Because the stored information is destroyed in order to read the signal “1”, the device is referred to as DRO type.

A typical NDRO type device has memory cells composed of transistors which have gates of a metal/ferroelectric substance (e.g., Lead Zirconate Titanate (PZT), Lead Lanthanum Zirconate Titanate (PLZT), Strontium Bismuth Tantalite (SBT) or the like)/silicon. The polarization direction of the ferroelectric substance changes in response to the polarity of the gate voltage, and a channel is enabled or disabled to have electric conductivity in response to the polarization direction, so that information “1” or “0” may be stored. The polarization of the gate ferroelectric substance constituting the channel may be maintained even when power is interrupted to read out the enabled or disabled electric conductivity of the channel, so that the information may be continuously read out by the read signal without affecting the polarization direction of the gate ferroelectric substance. That is, the NDRO type, unlike the DRO type, does not require the polarization direction stored in the gate by the read signal to be reversed. Accordingly, a NDRO ferroelectric random access memory (FRAM) device may have a considerably simplified memory cell structure compared to the DRO type, and thus may have many advantages in terms of integration density, process facilitation, manufacturing cost reduction, characteristic enhancement and the like, and may have the potential to replace the various memory devices used in cellular communications memory devices, hard disks, flash memory, electrically erasable and programmable read only memory (EEPROM), and so forth.

An important feature of a ferroelectric gate transistor in a NDRO-FRAM cell lies in the gate structure, which is may have a metal/ferroelectric/semiconductor (MFS) structure and/or a metal/ferroelectric/insulator/semiconductor (MFIS) structure. Considerable research has been conducted into the most suitable ferroelectric materials for use in such a gate structure, and examples of commercially available current ferroelectric substances include PB(Zr, Ti)O₃(PZT) and Ba(Sr, Ti)O₃(BST) materials from companies such as U.S.-based Ramtron and Japanese-based ROHM, and SrBi₂Ta₂O₉(SBT), SrBi₂Nb₂O₉(SBN), and YMnO₃ materials from companies such as U.S.-based Symmetrix. Accordingly, conventional ferroelectric gate transistor may use an MFS structure or an MFIS structure, both of which use PZT, BST, SBT, SBN, and YMO-based ferroelectric substances. Here, the metal may include Pt, Ir, IrO₂ and/or a multi-layered structure of Pt/IrO₂ and Ir/IrO₂, and the semiconductor may be silicon or a silicon-on-insulator (SOI).

FIG. 1 illustrates a symbol for a one-transistor type NDRO-FRAM cell, which includes a drain D, a gate G, a bulk B, and a source S. FIGS. 2A and 2B are cross-sectional views for explaining a read method for the one transistor type NDRO-FRAM cell of FIG. 1. Referring to FIGS. 1, 2A, and 2B, the gate G is disposed on the bulk B. The gate G may include a ferroelectric patter 20 and a word line 30, which are stacked. The source S and the drain D are disposed within the bulk B adjacent to the gate G. Typical operating conditions for the one transistor type NDRO-FRAM cell of FIGS. 1, 2A and 2B are shown in Table 1 below:

TABLE 1

| | Gate(G) | Bulk(B) | Drain(D) | Source(S) |
|---|---|---|---|---|
| Write operation | +Vcc/−Vcc | ground | floating or | floating or |
| (‘1’/‘0’) | | | ground | ground |
| Read operation | floating | floating | +Vcc | ground |

In a write operation for the NDRO-FRAM cell, the bulk B may be grounded, −Vcc may be applied to the gate G to write a “0”, +Vcc may be applied to the gate G to write a “1”, and the drain D and the source S should be floated or grounded. This is for polarizing the ferroelectric gate of the NDRO-FRAM cell in different directions (upward and downward in FIG. 3) in response to a positive or negative voltage polarity. In some embodiments, the gate G may be grounded and +Vcc may be applied to the bulk B to write a “0”, and the gate G may be grounded and −Vcc may be applied to the bulk B to write a “1”. After data of “0” or “1” is written, the gate voltage need not be applied again, and the NDRO-FRAM cell may store data of “0” or “1”.

In a read operation, +Vcc is applied to the drain D, the source S is grounded, and the bulk B and the gate G are floated as shown in FIG. 2A. When a “1” is already written in the NDRO-FRAM cell, the already formed polarization dipole of the ferroelectric pattern 20 applies a positive (+) voltage to a gate channel C1, so that the gate channel C1 is turned on and the drain current Id flows in the channel. This current may be sensed to thereby read the data level of “1”. As shown in FIG. 2B, when “0” is already written in the NDRO-FRAM cell, the polarization dipole of the ferroelectric pattern 20 has its direction reversed, such that a negative (−) voltage is applied to a gate channel C2, so that the gate channel C2 is turned off and the drain current is impeded to thereby read the data level of “0”.

An example of applying cells in an array form was disclosed in Korea Patent Registration No. 10-0365296. According to a cell array structure described in Korea Patent Registration No. 10-0365296, a contact is formed to connect a terminal to each of the source S and the drain D per each cell, so that integration of the memory device may be limited.

### SUMMARY OF THE INVENTION

In some embodiments of the present invention, a memory device includes a layer of parallel strings of ferroelectric gate transistors on a substrate, the layer of parallel strings including a plurality of parallel line-shaped active regions and a plurality of word lines extending in parallel transversely across the active regions and disposed on ferroelectric patterns on the active regions. A string select gate line may extend transversely across the active regions in parallel with the word lines. A ground select gate line may extend transversely across the active regions in parallel with the word lines.

In further embodiments, the layer of parallel strings includes first and second overlapping layers of parallel strings including respective first and second layers of parallel line-shaped active regions and respective first and second pluralities of word lines extending in parallel across respective ones of the first and second layers of active regions and disposed on ferroelectric patterns on the active region. The memory device further includes respective first and second layer select lines extending across respective ones of the first and second layers of active regions in parallel with the respective first and second pluralities of word lines. A string select gate line may extend transversely across one of the layers of active regions in parallel with the word lines thereon. A ground select gate line may extend transversely across one of the layers of active regions in parallel with the word lines thereon.

In further embodiments of the present invention, a memory device includes a semiconductor substrate and an isolation layer defining a line-shaped active region in the semiconductor substrate. A string select gate and a ground select gate are spaced apart on the substrate and extend across the active region. A ferroelectric pattern is disposed on the active region between the string select gate and the ground select gate. A word line is disposed on the ferroelectric pattern and extends across the active region between the string select gate and the ground select gate. Source/drain regions may be disposed in the active region between adjacent ones of the string select gate, the word line and the ground select gate. The line-shaped active region may include a line-shaped well disposed therein having a first conductivity type and the source/drain regions may be disposed in the line-shaped well and have a second conductivity type. In some embodiments, the device further includes an interfacial insulating layer pattern or a stack including an interfacial insulating layer pattern and a lower electrode interposed between the active region and the ferroelectric pattern.

In further embodiments of the present invention, the word line includes a first word line and the memory device further includes a lower interlayer insulating layer on the first word line, a source line extending through the lower interlayer insulating layer to contact the active region on a side of the ground select gate opposite the word line, an upper interlayer insulating layer covering the source line and the lower interlayer insulating layer and a bit line extending through the upper and lower interlayer insulating layers to contact the active region on a side of the string select gate electrode opposite the word line. In some embodiments, the ferroelectric patterns include first ferroelectric patterns, the word line includes a first word line, and the memory device further includes a first layer select gate on the substrate and crossing the active region between the string select gate and the ground select gate, an interlayer insulating layer covering the string select gate, the first word lines, the first layer select gate and the ground select gate, a line-shaped semiconductor body pattern on the interlayer insulating layer and extending parallel to the active region, a first contact plug extending through the line-shaped semiconductor body pattern and the interlayer insulating layer to contact the active region between the ground select gate and the first word line, a second contact plug extending through the line-shaped semiconductor body pattern and the interlayer insulating layer to contact the active region between the string select gate and the first word line, a second layer select gate extending across the line-shaped semiconductor body pattern between the first and second contact plugs, a second ferroelectric pattern on the line-shaped semiconductor body pattern between the first and second contact plugs, and a second word line on the second ferroelectric pattern and extending across the semiconductor body pattern between the first and second contact plugs.

Additional embodiments of the present invention provide a memory device including a semiconductor substrate and an isolation region defining a plurality of line-shaped active regions disposed in parallel in the semiconductor substrate. The device further includes respective ferroelectric patterns on respective ones of the active regions, a word line extending transversely across the active regions and disposed on the ferroelectric patterns, source/drain regions in the active regions on respective first and second sides of the word line, a common source line on the substrate and connected to the source/drain regions on the first side of the word line and respective bit lines on the substrate and connected to respective ones of the source/drain regions on the second side of the word line. The device may further include respective line-shaped wells in respective ones of the line-shaped active regions, and the source/drain regions may be disposed in the line-shaped wells.

In some embodiments, the ferroelectric patterns include first ferroelectric patterns, the word line includes a first word line, the common source line includes a first common source line, the bit lines include first bit lines, and the memory device further includes a layer isolation insulating layer on the first bit lines, a plurality of line-shaped semiconductor body patterns on the layer isolation layer insulating layer and extending parallel to the line-shaped active regions, second ferroelectric patterns on the semiconductor body patterns, a second word line extending transversely across the semiconductor body patterns parallel to the first word line and disposed on the second ferroelectric patterns, second source/drain regions in the semiconductor body patterns on respective first and second sides of the second word line, a second common source line on the substrate and electrically connected to the second source/drain regions on the first side of the second word line, and a second plurality of bit lines on the substrate and electrically connected to the second source/drain regions on the second side of the second word line.

Additional embodiments provide methods of fabricating a memory device. An isolation region defining a line-shaped active region in a substrate is formed. A string select gate structure, a ground select gate structure and a word line structure extending in parallel across the active region are formed. The word line structure is disposed between the string select gate structure and the ground select gate structure and including a ferroelectric pattern on the active region and a word line on the ferroelectric pattern. A source line contacting the active region on a side of the ground select gate structure opposite the word line structure is formed. A bit line contacting the active region on a side of the string select gate structure opposite the word line structure is formed.

Further method embodiments include forming an isolation layer defining a plurality of line-shaped active regions disposed in parallel in a semiconductor substrate, forming a word line structure on the substrate crossing the active regions, the word line structures including respective ferroelectric patterns on the active regions and a word line on the ferroelectric patterns, implanting impurity ions into the active regions using the word line structure as an ion implantation mask to form source/drain regions in the active regions, forming a common source line on the substrate electrically connecting the first source regions on a first side of the word line structure, and forming respective bit lines on the substrate and connected to respective ones of the source/drain regions on the second side of the word line structure.

Still further embodiments provide write methods for a memory device including a plurality of parallel line-shaped semiconductor wells and a plurality of ferroelectric word line structures including parallel word lines extending across the line-shaped wells and disposed on respective ferroelectric patterns. A write method includes simultaneously applying a first voltage to a selected well, floating others of the wells, applying a second voltage to a selected word line, and floating others of the word lines to polarize one of the ferroelectric patterns interposed between the selected word line and the selected well. The memory device may include source/drain regions in the wells adjacent the word line structures, and simultaneously applying a first voltage to a selected well, floating others of the wells, applying a second voltage to a selected word line, and floating others of the word lines to polarize one of the ferroelectric patterns interposed between the selected word line and the selected well may include simultaneously applying the first voltage to the selected well, floating the others of the wells, applying the second voltage to the selected word line, floating the others of the word lines and floating or grounding the source/drain regions to polarize the one of the ferroelectric patterns interposed between the selected word line and the selected well.

Read methods for a memory device including a plurality of parallel line-shaped semiconductor wells, a plurality of ferroelectric word line structures including parallel word lines extending across the line-shaped wells and disposed on ferroelectric patterns on the line-shaped wells, and source/drain regions disposed in the wells between the word line structures include, while simultaneously grounding a selected well, floating or grounding a selected word line and applying a pass voltage to others of the word lines, determining a current passing through a channel controlled by the selected word line.

In some embodiments, the memory device includes first and second stacked layers of parallel line-shaped wells connected such that a respective well from the first layer is paralleled with a respective well from the second layer, respective first and second pluralities of word line structures including parallel word lines extending across respective ones of the first and second layers of parallel line-shaped wells and disposed on ferroelectric patterns on the wells, respective string select gates on one of the first and second wells and configured to couple respective paralleled wells from the first and second layers to respective bit lines, respective ground select gates on of the first and second wells and configured to couple respective parallels wells from the first and second layers to a source line, and respective first and second layer select gates extending across respective ones of the first and second layers of wells. Simultaneously grounding a selected well, floating or grounding a selected word line and applying a pass voltage to others of the word lines, determining a current passing through a channel controlled by the selected word line may include, while simultaneously grounding a selected well from the first and second layers of wells, applying a turn-on voltage to a string select gate and a ground select gate associated with the selected well, applying a turn-on voltage to a selected one of the first and second layer select gates, and floating or grounding a selected word line and applying the pass voltage to others of the word lines, determining a current passing through a channel in the selected well controlled by the selected word line.

In still further read method embodiments, a memory device including a plurality of parallel line-shaped semiconductor wells, a plurality of ferroelectric word line structures including parallel word lines extending across the line-shaped wells and disposed on ferroelectric patterns on the line-shaped wells, and source/drain regions disposed in the wells adjacent the word line structure is read by, while simultaneously grounding a selected well, floating or grounding a selected word line, applying an off voltage to non-selected word lines and applying a read voltage to a source/drain region adjacent the selected word line, determining a current flowing through a channel controlled by the selected word line.

An exemplary embodiment of the present invention provides flash memory devices employing a ferroelectric layer suitable for highly integrating one-transistor type NDRO-FRAM cells as an information storage element.

Another exemplary embodiment of the present invention provides methods of fabricating flash memory devices employing a ferroelectric layer suitable for highly integrating one transistor type NDRO-FRAM cells as an information storage element.

Still another exemplary embodiment of the present invention provides read and write methods of flash memory devices employing a ferroelectric layer as an information storage element.

In one aspect, the invention is directed to a flash memory device employing a ferroelectric layer as an information storage element. The flash memory device includes a semiconductor substrate having line-shaped active regions defined by an isolation layer. A string select gate electrode and a ground select gate electrode are disposed across the active regions. A first word line is disposed across the active regions between the string select gate electrode and the ground select gate electrode. A first ferroelectric pattern is interposed between the first word line and the active regions.

In some exemplary embodiments of the present invention, first source/drain regions may be disposed within the active regions adjacent to the string select gate electrode, the ground select gate electrode, and the first word line.

In other exemplary embodiments, line-shaped wells may be disposed within the line-shaped active regions, respectively.

In still other exemplary embodiments, a lower interlayer insulating layer may be disposed on the semiconductor substrate having the first word line. A common source line may be disposed through the lower interlayer insulating layer, and electrically connected to the active regions adjacent to the ground select gate electrode and disposed opposite to the first word line. An upper interlayer insulating layer may be disposed to cover the common source line and the lower interlayer insulating layer. Bit lines may be disposed through the upper and lower interlayer insulating layers, and electrically connected to the respective active regions adjacent to the string select gate electrode and disposed opposite to the first word line.

In yet other exemplary embodiments, a first layer select gate electrode may be disposed across the active regions between the first word line and the ground select gate electrode. Line-shaped semiconductor body patterns may be disposed parallel to the line-shaped active regions on the lower interlayer insulating layer. First and second contact plugs may be disposed, which sequentially penetrate the line-shaped semiconductor body patterns and the lower interlayer insulating layer, and are electrically connected to the respective active regions between the ground select gate electrode and the first layer select gate electrode and between the string select gate electrode and the first word line. A second word line may be disposed across the semiconductor body patterns between the first and second contact plugs, and parallel to the first word line. A second ferroelectric pattern may be interposed between the second word line and the semiconductor body patterns. A second layer select gate electrode may be disposed across the semiconductor body patterns between the first contact plug and the second word line.

In another aspect, the invention is directed to a flash memory device employing a ferroelectric layer as an information storage element. The flash memory device includes a semiconductor substrate having line-shaped active regions defined by an isolation layer. First word lines are disposed across the active regions. First ferroelectric patterns are interposed between the first word lines and the active regions, respectively. First source regions and first drain regions are disposed within the active regions adjacent to the first word lines. A first common source line is disposed to electrically connect the first source regions. A lower interlayer insulating layer is disposed to cover the substrate having the first common source line. First bit lines are disposed parallel to the active regions on the lower interlayer insulating layer, and extend into the lower interlayer insulating layer to electrically connect the first drain regions.

In some exemplary embodiments of the present invention, line-shaped wells may be disposed within the line-shaped active regions, respectively.

In other exemplary embodiments, a layer isolation insulating layer may be disposed to cover the lower interlayer insulating layer and the first bit lines. Line-shaped semiconductor body patterns may be disposed parallel to the line-shaped active regions on the layer isolation insulating layer. Second word lines may be disposed across the semiconductor body patterns and parallel to the first word lines. Second ferroelectric patterns may be interposed between the second word lines and the semiconductor body patterns, respectively. Second source regions and second drain regions may be disposed within the semiconductor body patterns adjacent to the second word lines. A second common source line may be disposed to electrically connect the second source regions. An upper interlayer insulating layer may be disposed to cover the substrate having the second common source line. Second bit lines may be disposed parallel to the semiconductor body patterns on the upper interlayer insulating layer, and extend into the upper interlayer insulating layer to electrically connect the second drain regions.

In still another aspect of the invention, the invention is directed to methods of fabricating a flash memory device employing a ferroelectric layer as an information storage element. The methods include forming an isolation layer defining line-shaped active regions within a semiconductor substrate. A string select gate, a ground select gate, and a first cell gate are formed across the active regions on the semiconductor substrate, and the first cell gate is formed between the string select gate and the ground select gate. The first cell gate has a ferroelectric pattern and a first word line, which are stacked.

In some exemplary embodiments of the present invention, line-shaped wells may be formed within the line-shaped active regions.

In other exemplary embodiments, first source/drain regions may be formed within the substrate using the string select gate, the ground select gate, and the first cell gate as ion implantation masks. A lower interlayer insulating layer may be formed on the substrate having the first source/drain regions. A common source line may be formed through the interlayer insulating layer, and electrically connected to the active regions adjacent to the ground select gate and disposed opposite to the first cell gate. An upper interlayer insulating layer may be formed to cover the common source line and the lower interlayer insulating layer. Bit lines may be formed, which penetrate the upper and lower interlayer insulating layer and are electrically connected to the respective active regions adjacent to the string select gate and disposed opposite to the first cell gate.

In still other exemplary embodiments, a first layer select gate may be formed across the active regions between the ground select gate and the first cell gate while the select gates are formed. Prior to the formation of the upper interlayer insulating layer, line-shaped semiconductor body patterns may be formed parallel to the line-shaped active regions on the lower interlayer insulating layer. Subsequently, a second cell gate and a second layer select gate may be formed parallel to the first cell gate and across the semiconductor body patterns. Second source/drain regions may be formed within the semiconductor body patterns using the second cell gate and the second layer select gate as ion implantation masks. First and second contact plugs may be formed through the lower interlayer insulating layer to electrically connect the first source/drain regions between the ground select gate and the first layer select gate and between the string select gate and the first cell gate with the second source/drain regions within the semiconductor body patterns, respectively. In this case, the second layer select gate may be formed between the first contact plug and the second cell gate.

In yet another aspect of the invention, the invention is directed to methods of fabricating a flash memory device employing a ferroelectric layer as an information storage element. The methods include forming an isolation layer defining line-shaped active regions within a semiconductor substrate. First cell gates are formed across the active regions on the semiconductor substrate, and each of the first cell gates has a ferroelectric pattern and a first word line, which are stacked. Impurity ions are implanted into the active regions using the first cell gates as ion implantation masks to form first source regions and first drain regions. A first common source line is formed to electrically connect the first source regions. A lower interlayer insulating layer is formed to cover the substrate having the first common source line. First bit lines are formed on the lower interlayer insulating layer, which are disposed parallel to the active regions and extend into the lower interlayer insulating layer to electrically connect the first drain regions.

In some exemplary embodiments of the present invention, line-shaped wells may be formed within the line-shaped active regions.

In other exemplary embodiments, a layer isolation insulating layer may be formed to cover the lower interlayer insulating layer and the first bit line. Subsequently, line-shaped semiconductor body patterns may be formed parallel to the line-shaped active regions on the layer isolation insulating layer. Second cell gates may be formed parallel to the first cell gates and across the semiconductor body patterns on the layer isolation insulating layer. Impurity ions may be implanted into the semiconductor body patterns using the second cell gates as ion implantation masks to form second source regions and second drain regions. A second common source line may be formed to electrically connect the second source regions. An upper interlayer insulating layer may be formed to cover the substrate having the second common source line. Second bit lines may be formed on the upper interlayer insulating layer, which are disposed parallel to the semiconductor body patterns and extend into the upper interlayer insulating layer to electrically connect the second drain regions.

In yet another aspect of the invention, the invention is directed to write methods of a flash memory device employing a ferroelectric layer as an information storage element. The write methods include applying a first voltage to one well selected from a plurality of line-shaped wells disposed within a substrate, and floating non-selected wells. A second voltage is applied to one word line among a plurality of word lines crossing the wells to polarize a ferroelectric pattern interposed between the word line and the well, and non-selected word lines are floated.

In some exemplary embodiments of the present invention, polarizing the ferroelectric pattern may be performed when the first voltage is a ground voltage and the second voltage is a +Vcc voltage higher than the first voltage.

In other exemplary embodiments, polarizing the ferroelectric pattern may be performed when the first voltage is a ground voltage and the second voltage is a −Vcc voltage lower than the first voltage.

In yet another aspect of the invention, the invention is directed to read methods of a flash memory device employing a ferroelectric layer as an information storage element. The methods include grounding a first line-shaped well formed within a semiconductor substrate and a second line-shaped well formed within a semiconductor body pattern over the first line-shaped well. A ground select transistor and a string select transistor formed in the first line-shaped well are turned on, and the ground select transistor and the string select transistor adopt a ground select gate electrode and a string select gate electrode crossing the first line-shaped well, respectively. A first layer select transistor formed in the first line-shaped well between the ground select gate electrode and the string select gate electrode and/or a second layer select transistor formed in the second line-shaped well is turned on to select one of the first and second line-shaped wells, and the first and second layer select transistors have source regions electrically connected to each other via first contact plugs penetrating the second line-shaped well. A cell gate electrode of a selected cell transistor among a plurality of cell transistors, which are formed in the selected line-shaped well and serially connected to each other, is floated or grounded. Non-selected cell transistors are turned on by applying a pass voltage to cell gate electrodes of the non-selected cell transistors. The cell gate electrodes extend across the selected line-shaped well to act as a word line.

In some exemplary embodiments of the present invention, a read voltage may be applied between a string source region and a string drain region, the string source region may be formed within the first line-shaped well adjacent to the ground select gate electrode and disposed opposite to the string select gate electrode, and the string drain region may be formed within the first line-shaped well adjacent to the string select gate electrode and disposed opposite to the ground select gate, so that a cell current flowing through the selected cell transistor may be sensed. The cell current may be determined by a polarization state of a ferroelectric pattern interposed between the selected line-shaped well and the cell gate electrode of the selected cell transistor.

In yet another aspect of the invention, the invention is directed to read methods of a flash memory device employing a ferroelectric layer as an information storage element. The methods include grounding a line-shaped well disposed within a substrate. One selected from a plurality of cell gates crossing the well is floated or grounded to select a cell disposed between the selected cell gate and the well. An off voltage is applied to non-selected cell gates. Each of the cell gates has a ferroelectric pattern and a word line, which are stacked. A read voltage is applied between a drain region adjacent to the selected cell and a common source region electrically connected to a source region adjacent to the selected cell, so that a current flowing through the selected cell is sensed.

### BRIEF DESCRIPTION OF THE DRAWINGS

FIG. 1 shows a symbol for a one-transistor type NDRO-FRAM cell.

FIGS. 2A and 2B are cross-sectional views illustrating operations of the one transistor type NDRO-FRAM cell of FIG. 1.

FIG. 3 is a plan view illustrating operations for fabricating a flash memory device in accordance with some exemplary embodiments of the present invention.

FIGS. 4A, 5A, 6A, 7A, 8A, and 9A are cross-sectional views taken along line I-I′ of FIG. 3, and FIGS. 4B, 5B, 6B, 7B, 8B, and 9B are cross-sectional views taken along line II-II′ of FIG. 3.

FIG. 10 is a plan view illustrating operations for fabricating a flash memory device in accordance with other exemplary embodiments of the present invention.

FIGS. 11A, 12A, 13A, and 14A are cross-sectional views taken along line III-III′ of FIG. 10, and FIGS. 11B, 12B, 13B, and 14B are cross-sectional views taken along line IV-IV′ of FIG. 10.

FIG. 15A is a circuit diagram illustrating write operations for a flash memory device in accordance with some exemplary embodiments of the present invention.

FIG. 15B is a circuit diagram illustrating read operations for a flash memory device in accordance with some exemplary embodiments of the present invention.

FIG. 15C is a circuit diagram illustrating read operations for a flash memory device with select gates including a ferroelectric pattern and a gate electrode, which are stacked according to some exemplary embodiments of the present invention.

FIG. 16A is a circuit diagram illustrating write operations for a flash memory device in accordance with further exemplary embodiments of the present invention.

FIG. 16B is a circuit diagram illustrating read operations for a flash memory device in accordance with further exemplary embodiments of the present invention shown.

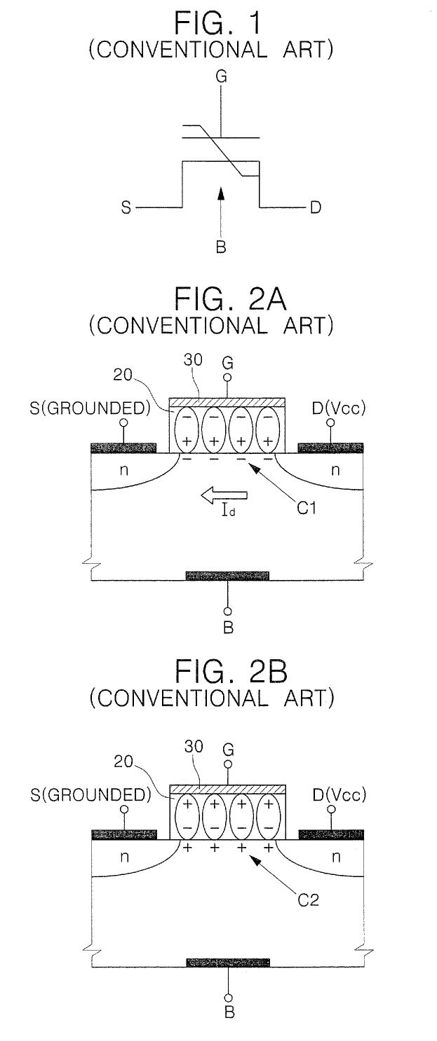

### DETAILED DESCRIPTION OF EMBODIMENTS OF THE INVENTION

The present invention will be described more fully hereinafter with reference to the accompanying drawings, in which embodiments of the invention are shown. However, this invention should not be construed as limited to the embodiments set forth herein. Rather, these embodiments are provided so that this disclosure will be thorough and complete, and will fully convey the scope of the invention to those skilled in the art. In the drawings, the thickness of layers and regions are exaggerated for clarity. Like numbers refer to like elements throughout. As used herein the term “and/or” includes any and all combinations of one or more of the associated listed items.

The terminology used herein is for the purpose of describing particular embodiments and is not intended to be limiting of the invention. As used herein, the singular forms “a”, “an” and “the” are intended to include the plural forms as well, unless the context clearly indicates otherwise. It will be further understood that the terms “includes” and/or “including,” when used in this specification, specify the presence of stated features, integers, steps, operations, elements, and/or components, but do not preclude the presence or addition of one or more other features, integers, steps, operations, elements, components, and/or groups thereof.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Embodiments of the present invention are described herein with reference to perspective illustrations that are schematic illustrations of idealized embodiments of the present invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, an etched region illustrated or described as a rectangle will, typically, have rounded or curved features. Thus, the regions illustrated in the figures are schematic in nature and their shapes are not intended to illustrate the precise shape of a region of a device and are not intended to limit the scope of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein. It will also be appreciated by those of skill in the art that references to a structure or feature that is disposed “adjacent” another feature may have portions that overlap or underlie the adjacent feature.

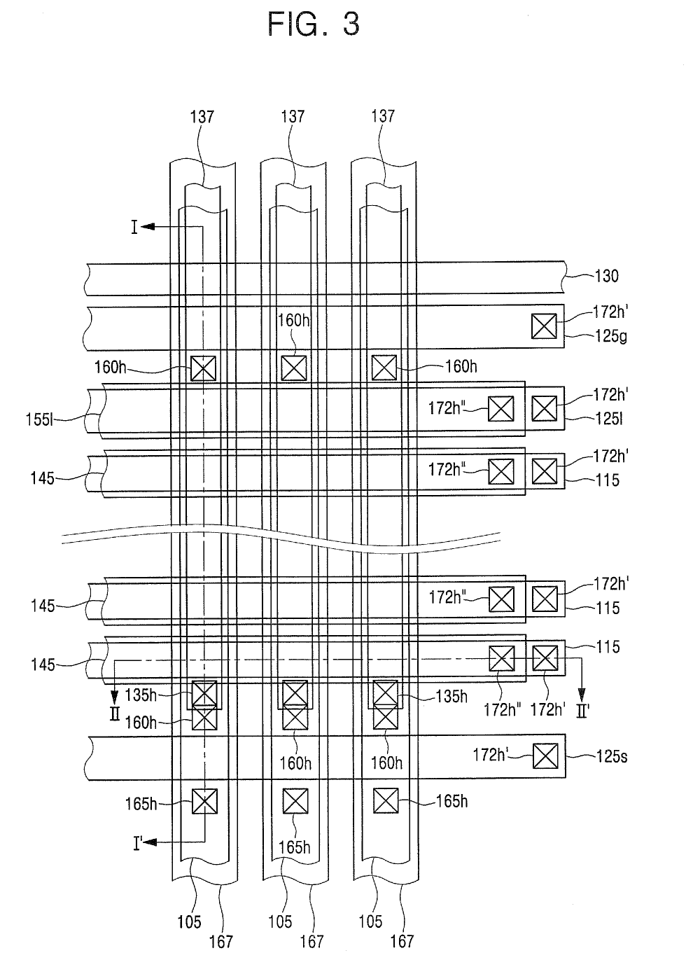

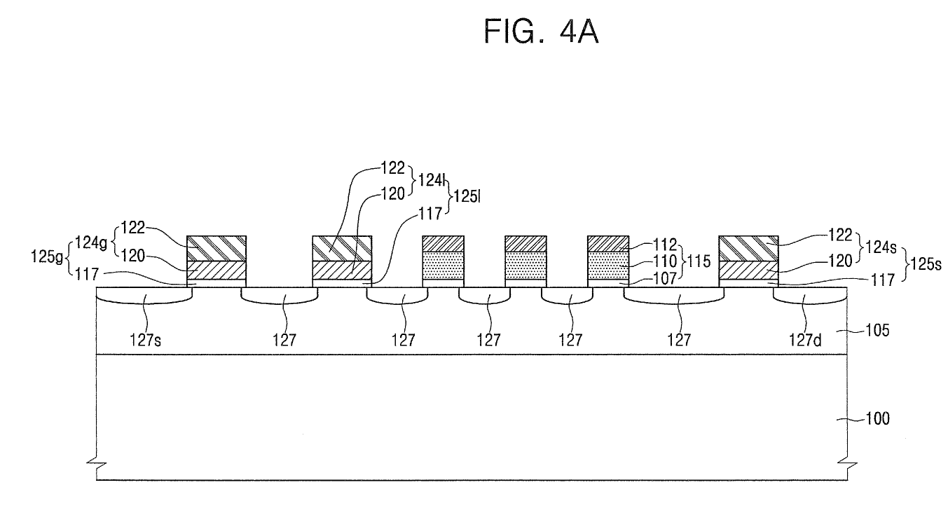

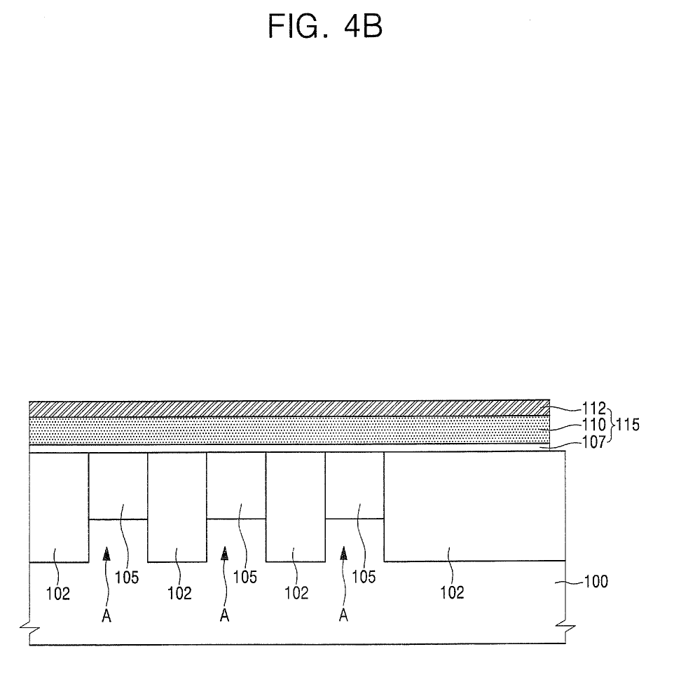

FIG. 3 is a plan view illustrating operations for fabricating a flash memory device in accordance with exemplary embodiments of the present invention. FIGS. 4A, 5A, 6A, 7A, 8A, and 9A are cross-sectional views taken along line I-I′ of FIG. 3, and FIGS. 4B, 5B, 6B, 7B, 8B, and 9B are cross-sectional views taken along line II-II′ of FIG. 3.

Referring to FIGS. 3, 4A, and 4B, an isolation layer 102 is formed to define a plurality of active regions A within a semiconductor substrate 100. The semiconductor substrate 100 may be a silicon substrate or a silicon on insulator (SOI) substrate. The active regions A may each have a generally line-shaped shape. The isolation layer 102 may be formed by a shallow trench isolation process. Impurity ions may be implanted into the semiconductor substrate using the isolation layer 102 as an ion implantation mask to form first line-shaped wells 105 within the active regions A. The first line-shaped wells 105 are separated by the isolation layer 102 so that a voltage may be independently applied to the first line-shaped wells 105. The first line-shaped wells 105 may be a p-type.

In some embodiments, a preliminary well may be formed within a cell region of the semiconductor substrate 100 prior to the formation of the isolation layer 102. Subsequently, the isolation layer 102 may be formed deeper than the preliminary well. As a result, the first line-shaped wells 105 separated by the isolation layer 102 may be formed, and a voltage may be independently applied to the first line-shaped wells 105.

First cell gates 115 crossing the active regions A are formed on the substrate having the first line-shaped wells 105. Each of the first cell gates 115 may include an interfacial insulating layer pattern 107, a ferroelectric pattern 110, and a first word line 112, which are stacked. The interfacial insulating layer pattern 107 may be omitted and/or a lower electrode (not shown) may be interposed between the interfacial insulating layer pattern 107 and the ferroelectric pattern 110.

The interfacial insulating layer pattern 107 may include a high-k dielectric layer. The interfacial insulating layer pattern 107 may include an aluminum oxide (Al₂O₃) layer, a hafnium oxide (HfO₂) layer, a hafnium aluminum oxide (HfAlOₓ) layer, a strontium titanium oxide (SrTiO) layer, a zirconium oxide (ZrO₂) layer, a tantalum oxide (Ta₂O₅) layer and/or a titanium oxide (TiO₂) layer. The ferroelectric pattern 110 may include a lead zirconate titanate (PbZrₓTi₁₋ₓO₃; PZT) layer, a bismuth lanthanum titanate (Bi₄₋ₓLaₓTi₃O₁₂; BLT) layer, a strontium bismuth tantalite (SrBi₂Ta₂O₅; SBT) layer and/or a lead germanium oxide (Pb₅Ge₄O₁₁; PGO) layer. The first word line 112 may include platinum (Pt), ruthenium (Ru), iridium (Ir) and/or iridium oxide (IrO₂).

A string select gate 125s, a ground select gate 125g, and a first layer select gate 125l, which are parallel to the first cell gates 115 and cross the active regions A, may be formed on the substrate having the first cell gates 115. The first layer select gate 125l may be formed between the ground select gate 125g and the first cell gate 115.

The string select gate 125s may include a gate insulating layer pattern 117 and a string select gate electrode 124s which are stacked. The ground select gate 125g may include a gate insulating layer pattern 117 and a ground select gate electrode 124g which are stacked. The first layer select gate 125l may include a gate insulating layer pattern 117 and a first layer select gate electrode 124l, which are stacked.

The gate insulating layer pattern 117 may include a high-k dielectric layer or a silicon oxide layer. Each of the select gate electrodes 124s, 124g, and 124l may include a polysilicon pattern 120 and a metal silicide pattern 122 which are stacked. The metal silicide pattern 122 may include tungsten silicide, cobalt silicide or nickel silicide. In some embodiments, each of the select gate electrodes 124s, 124g, and 124l may include a polysilicon pattern.

In some exemplary embodiments of the present invention, the select gate electrodes 125s, 125g, and 125l may have the same stacked structure as the first cell gates 115. That is, the first cell gates 115 and the select gate electrodes 125s, 125g, and 125l may be simultaneously formed.

Impurity ions may be implanted into the substrate using the first cell gates 115 and the select gates 125s, 125g, and 125l as ion implantation masks to form first source/drain regions 127. In some embodiments, after the first cell gates 115 are formed, impurity ions may be implanted into the substrate using the first cell gates 115 as ion implantation masks to form cell source/drain regions, and the select gates 125s, 125g, and 125l may be formed, which may be used as ion implantation masks to form select gate source/drain regions. The first source/drain regions 127 may be n-type impurity regions.

The first cell gates 115 overlapping the respective cell active regions A, and the first source/drain regions 127 adjacent to the first cell gates 115 may constitute first cell transistors. The string select gate 125s overlapping the cell active regions A, and the first source/drain regions 127 adjacent to the string select gate 125s may constitute a string select transistor. The ground select gate 125g overlapping the cell active regions A, and the first source/drain regions 127 adjacent to the ground select gate 125g may constitute a ground select transistor. The first layer select gate 125l overlapping the cell active regions A, and the first source/drain regions 127 adjacent to the first layer select gate 125l may constitute a first layer select transistor.

Cell active regions adjacent to the string select gate 125s and disposed opposite to the first cell gates 115 may be defined as drain regions 127d of the respective string select transistors. Cell active regions adjacent to the ground select gate 125g and disposed opposite to the first cell gates 115 may be defined as source regions 127s of the respective ground select transistors.

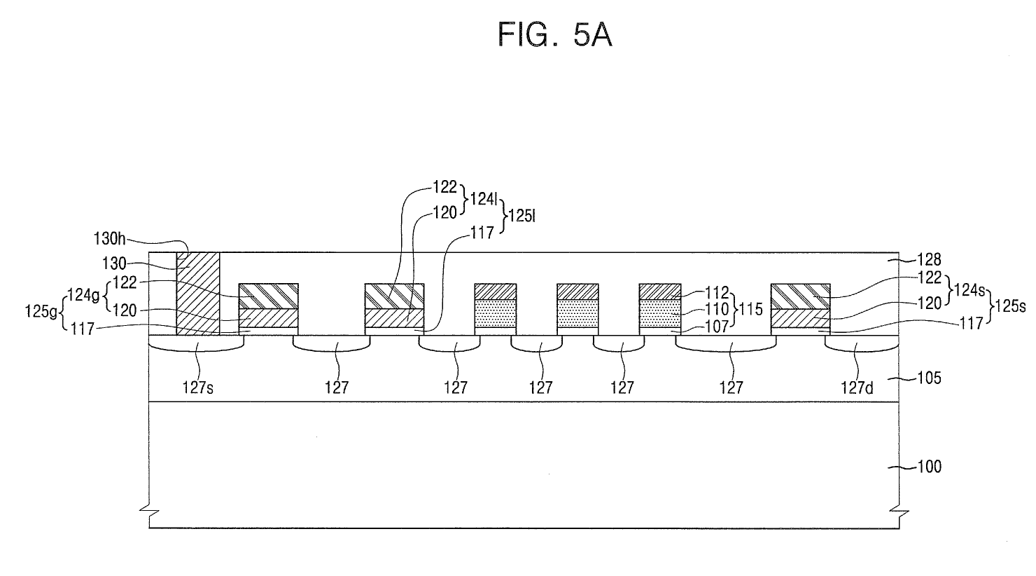

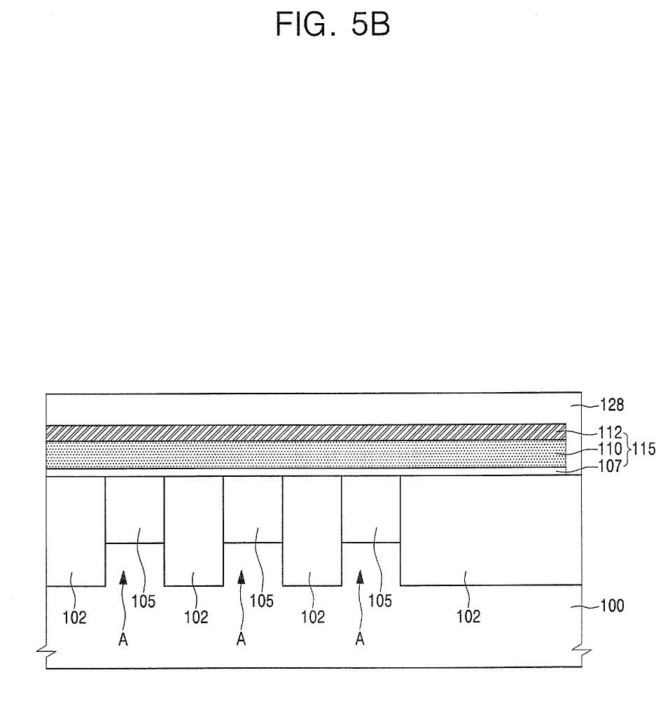

Referring to FIGS. 3, 5A, and 5B, a first lower interlayer insulating layer 128 is formed on the substrate having the gates 115, 125s, 125g, and 125l. The first lower interlayer insulating layer 128 may include a silicon oxide layer. The first lower interlayer insulating layer 128 is patterned to expose the source regions 127s adjacent to the ground select gate 125g and disposed opposite to the first cell gates 115 while a common source line trench 130h is formed parallel to the ground select gate 125g. A plug ion implantation process may be performed, which implants impurity ions into the active regions exposed by the common source line trench 130h to improve an ohmic contact.

Subsequently, a common source line 130 filling the common source line trench 130h is formed. Specifically, a conductive layer filling the common source line trench 130h is formed on the first lower interlayer insulating layer 128. A planarization process for exposing a top surface of the first lower interlayer insulating layer 128 is performed on the conductive layer to form the common source line 130 within the first lower interlayer insulating layer 128. The common source line 130 may include a polysilicon layer, a tungsten layer, an aluminum layer and/or stacked polysilicon and tungsten layers. The planarization process may be performed by an etch-back process or a chemical mechanical polishing process (CMP).

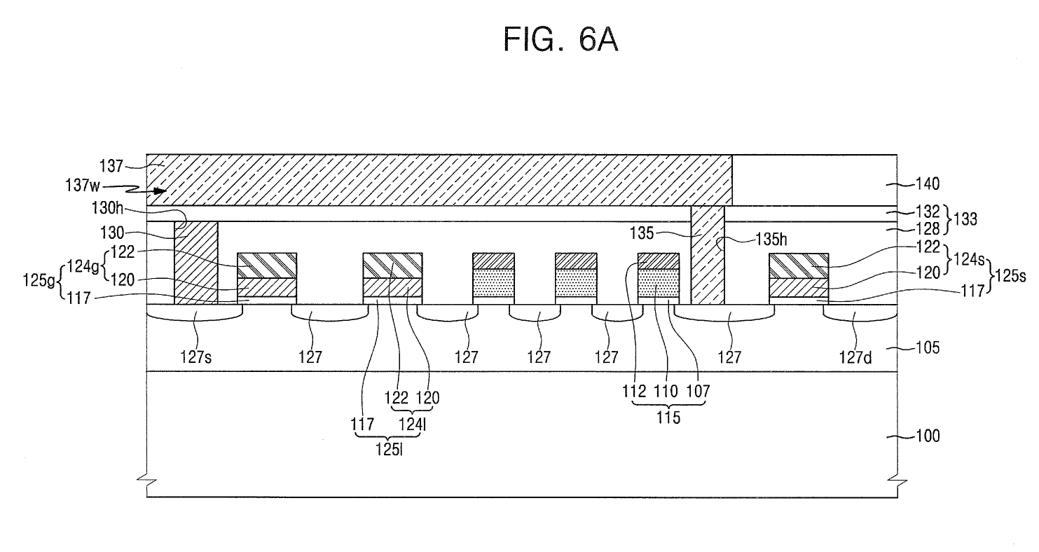

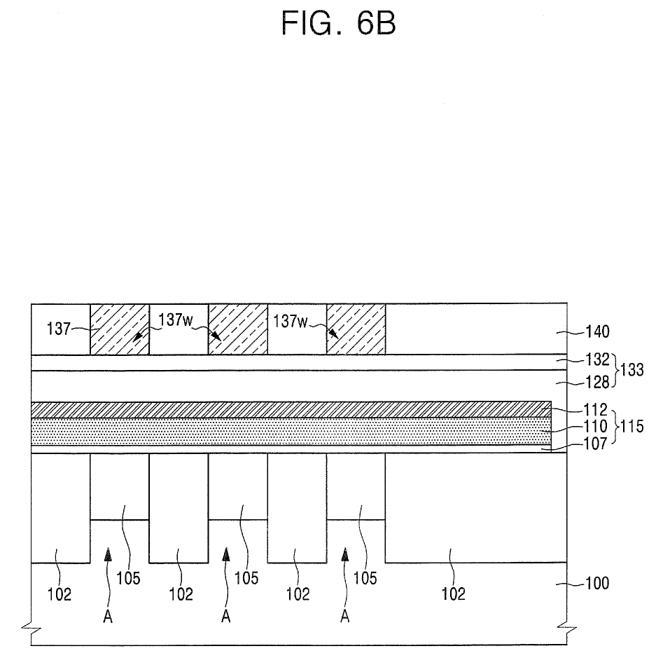

Referring to FIGS. 3, 6A, and 6B, a second lower interlayer insulating layer 132 is formed on the substrate having the common source line 130. The first and second lower interlayer insulating layers 128 and 132 may constitute a lower interlayer insulating layer 133. The lower interlayer insulating layer 133 may be patterned to form contact holes 135h exposing the first source/drain regions 127 between the first cell gate 115 and the string select gate 125s. Subsequently, a single crystalline layer filling the contact holes 135h may be formed by a single crystalline growth method and then planarized until the second lower interlayer insulating layer 132 is exposed to form single crystalline contact plugs 135 within the contact holes 135h. Subsequently, a non-single crystalline semiconductor layer may be formed on the substrate having the single crystalline contact plugs 135. The non-single crystalline semiconductor layer may be formed into a single crystalline semiconductor layer by a solid phase epitaxy (SPE) process or a laser annealing process. Subsequently, the single crystalline semiconductor layer may be patterned to form line-shaped semiconductor body patterns 137 parallel to the line-shaped active regions A.

In some exemplary embodiments of the present invention, after the contact holes 135h exposing the first source/drain regions 127 are formed, a single crystalline layer, which fills the contact holes 135h and covers the second lower interlayer insulating layer 132, may be formed by a single crystalline growth method. The single crystalline layer may be partially planarized to form single crystalline contact plugs 135 filling the contact holes 135h and at the same time to form a single crystalline semiconductor layer on the second lower interlayer insulating layer 132. Subsequently, the single crystalline semiconductor layer may be patterned to form line-shaped semiconductor body patterns 137 parallel to the line-shaped active regions A.

After an insulating layer is formed on the substrate having the line-shaped semiconductor body patterns 137, the insulating layer is planarized until the line-shaped semiconductor body patterns 137 are exposed. As a result, an upper isolation pattern 140 filling between the line-shaped semiconductor body patterns 137 may be formed. The upper isolation pattern 140 may include a silicon oxide layer.

In other exemplary embodiments, the single crystalline layer may be planarized until the second lower interlayer insulating layer 132 is exposed to form single crystalline contact plugs 135 within the contact holes 135h, and then an insulating layer may be formed on the substrate having the single crystalline contact plugs 135. Subsequently, the insulating layer may be patterned to form the upper isolation pattern 140 having line-shaped openings in a direction parallel to the line-shaped active regions A. The openings expose the single crystalline contact plugs 135. Subsequently, the single crystalline growth method may be employed using the single crystalline contact plug 135 as a seed layer so that a single crystalline semiconductor layer filling the openings may be formed. The single crystalline semiconductor layer may be planarized until the upper isolation pattern 140 is exposed to form line-shaped semiconductor body patterns 137. As such, when the upper isolation pattern 140 is formed in advance and the single crystalline growth method is employed to form the single crystalline semiconductor layer, it is not necessary to grow the single crystalline semiconductor layer in an unnecessary region, so that the process time of the single crystalline growth may be reduced.

Impurity ions may be implanted into the substrate having the line-shaped semiconductor body patterns 137 to form second line-shaped wells 137w within the line-shaped semiconductor body patterns 137. The second line-shaped wells 137w may be a p-type. The second line-shaped wells 137w may be formed within the entire line-shaped semiconductor body patterns 137.

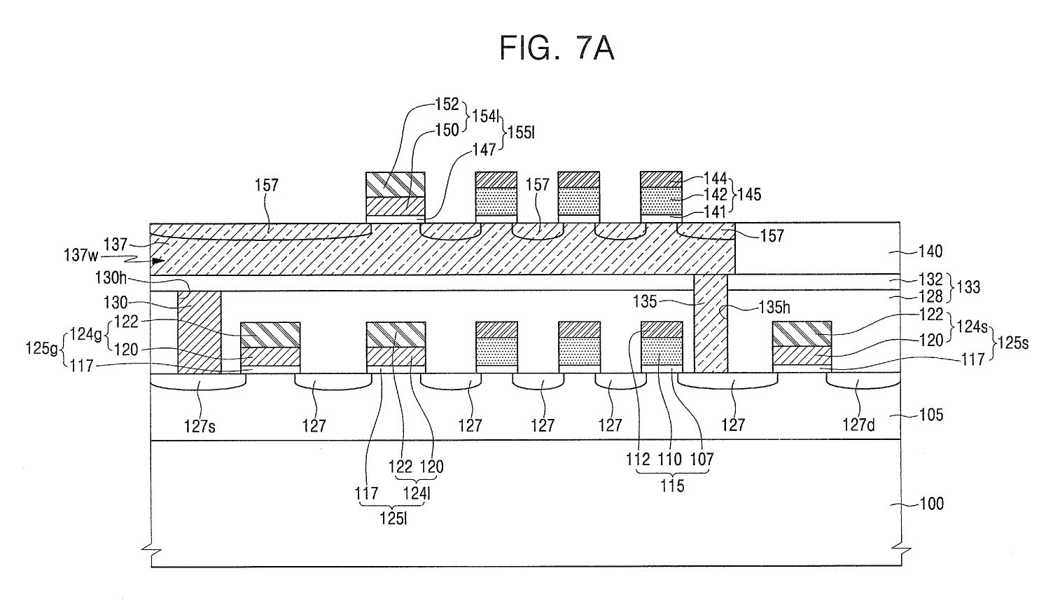

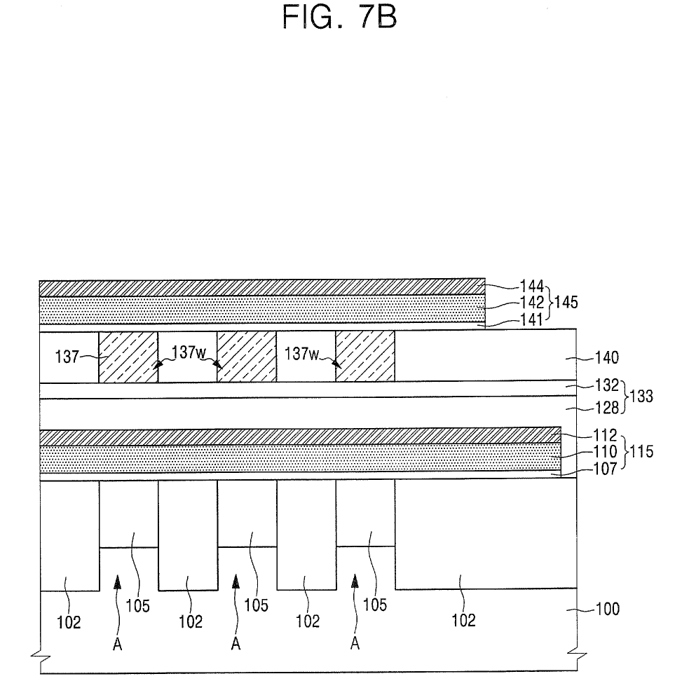

Referring to FIGS. 3, 7A, and 7B, second cell gates 145 crossing the line-shaped semiconductor body patterns 137 may be formed on the substrate having the line-shaped semiconductor body patterns 137. The second cell gates 145 may be parallel to the first cell gates 115, and may be formed over the first cell gates 115. Each of the second cell gates 145 may include an interfacial insulating layer pattern 141, a ferroelectric pattern 142, and a second word line 144, which are stacked. The interfacial insulating layer pattern 141 may be omitted and/or a lower electrode (not shown) may be interposed between the interfacial insulating layer pattern 141 and the ferroelectric pattern 142. The second cell gates 145 may have the same stacked structure as the first cell gates 115 and may include the same material as the first cell gates.

A second layer select gate 155l may be formed on the substrate having the second cell gates 145. The second layer select gate 155l may be formed over the first layer select gate 125l. The second layer select gate 155l may include a gate insulating layer pattern 147 and a second layer select gate electrode 154l, which are stacked. The gate insulating layer pattern 147 may include a high-k dielectric layer or a silicon oxide layer. The second layer select gate electrode 154l may include a polysilicon pattern 150 and a metal silicide pattern 152, which are stacked. The metal silicide pattern 152 may include tungsten silicide, cobalt silicide and/or nickel silicide. In some embodiments, the second layer select gate electrode 154l may include a polysilicon pattern.

In some exemplary embodiments of the present invention, the second layer select gate 155l may have the same stacked structure as the second cell gates 145. That is, the second cell gates 145 and the second layer select gate 155l may be simultaneously formed.

Impurity ions may be implanted into the line-shaped semiconductor body pattern 137 using the second cell gates 145 and the second layer select gate 155l as ion implantation masks to form second source/drain regions 157. The second source/drain regions 157 may be n-type impurity regions.

The second cell gates 145 overlapping the respective line-shaped semiconductor body patterns 137, and the second source/drain regions 157 adjacent to the second cell gates 145 may constitute second cell transistors. The second layer select gate 155l overlapping the line-shaped semiconductor body patterns 137, and the second source/drain regions 157 adjacent to the second layer select gate 155l may constitute a second layer select transistor.

Subsequently, the same processes as the processes of FIGS. 6A, 6B, 7A, and 7B may be repeatedly performed to further form additional semiconductor body patterns (not shown), cell gates (not shown), and layer select gates (not shown). In some embodiments, the processes of FIGS. 6A, 6B, 7A, and 7B may be skipped, and in this case, the first layer select gates 125l may also be omitted.

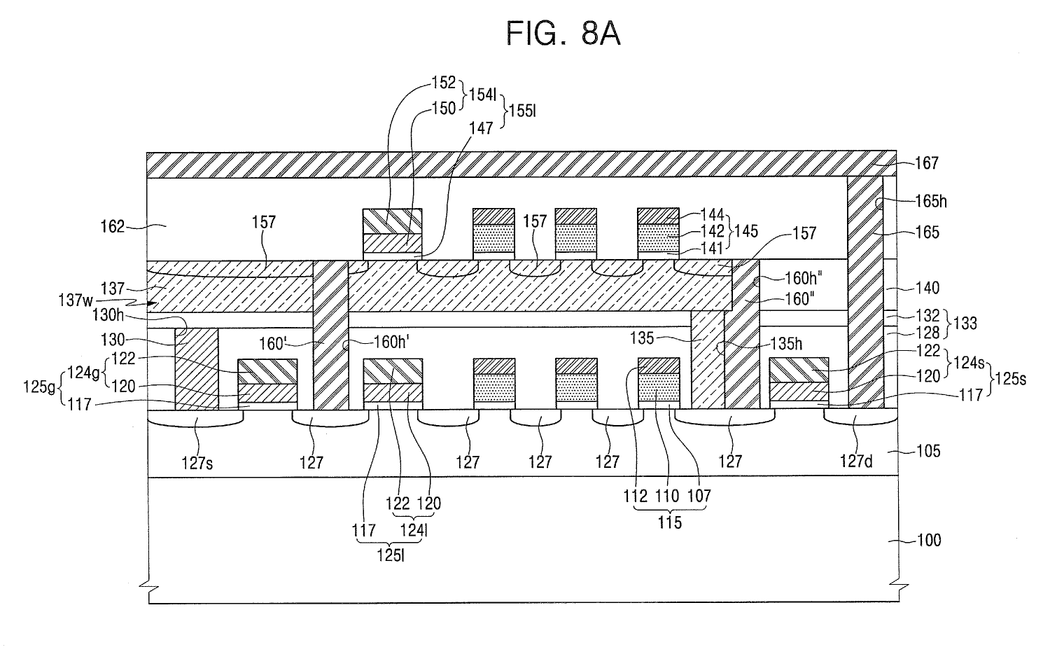

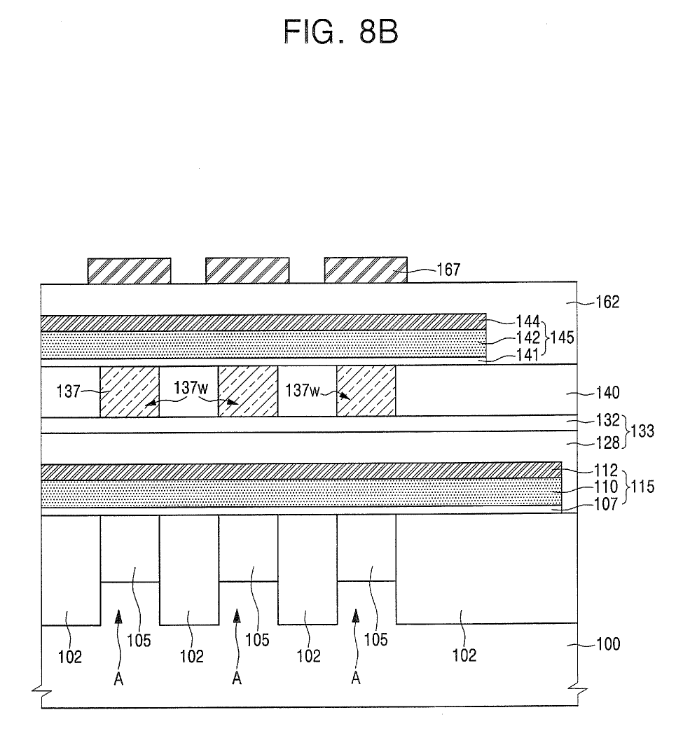

Referring to FIGS. 3, 8A, and 8B, the semiconductor body pattern 137 and the lower interlayer insulating layer 133 may be sequentially patterned to form first contact holes 160h′ exposing the first source/drain regions 127 between the first layer select gate 125l and the ground select gate 125g. The first contact holes 160h′ expose sidewalls of the semiconductor body patterns 137. In particular, the second source/drain regions 157 are preferably exposed to the sidewalls. In addition, the upper isolation pattern 140 and the lower interlayer insulating layer 133 may be sequentially patterned to form second contact holes 160h″ exposing the first source/drain regions 127 between the first cell gate 115 and the string select gate 125s while exposing the sidewalls of the semiconductor body patterns 137. The first and second contact holes 160h′ and 160h″ may be simultaneously formed. Each diameter of the first contact holes 160h′ is preferably smaller than each width of the semiconductor body patterns 137.

First and second contact plugs 160′ and 160″, which fill the respective first and second contact holes 160h′ and 160h″, may be formed. The first and second contact plugs 160′ and 160″ may include polysilicon having the same conductivity type as that of the first and second source/drain regions 127 and 157. For example, the first and second contact plugs 160′ and 160″ may include n-type polysilicon.

The second source/drain regions 157 may be electrically connected to the first source/drain regions 127 by the first and second contact plugs 160′ and 160h″. Specifically, the first contact plugs 160′ may electrically connect the source regions 127 and 157 to each other which are adjacent to the first and second layer select gates 125l and 155l, and the second contact plugs 160″ may electrically connect the drain regions 127 and 157 of the first and second cell gates 115 and 145 to each other which are adjacent to the string select gate 125s.

An upper interlayer insulating layer 162 may be formed on the substrate having the second cell gates 145 and the second layer select gate 155l. The upper interlayer insulating layer 162, the isolation pattern 140, and the lower interlayer insulating layer 133 may be sequentially patterned to form bit line contact holes 165h exposing the respective drain regions 127d adjacent to the string select gate 125s. Subsequently, a conductive layer may be formed, which fills the bit line contact holes 165h and covers the upper interlayer insulating layer 162. The conductive layer may be patterned to form bit line contact plugs 165 filling the bit line contact holes 165h and to simultaneously form bit lines 167 covering the bit line contact plugs 165 and running in a direction parallel to the active regions A. In some embodiments, the bit lines 167 may be formed after the bit line contact plugs 165 are formed.

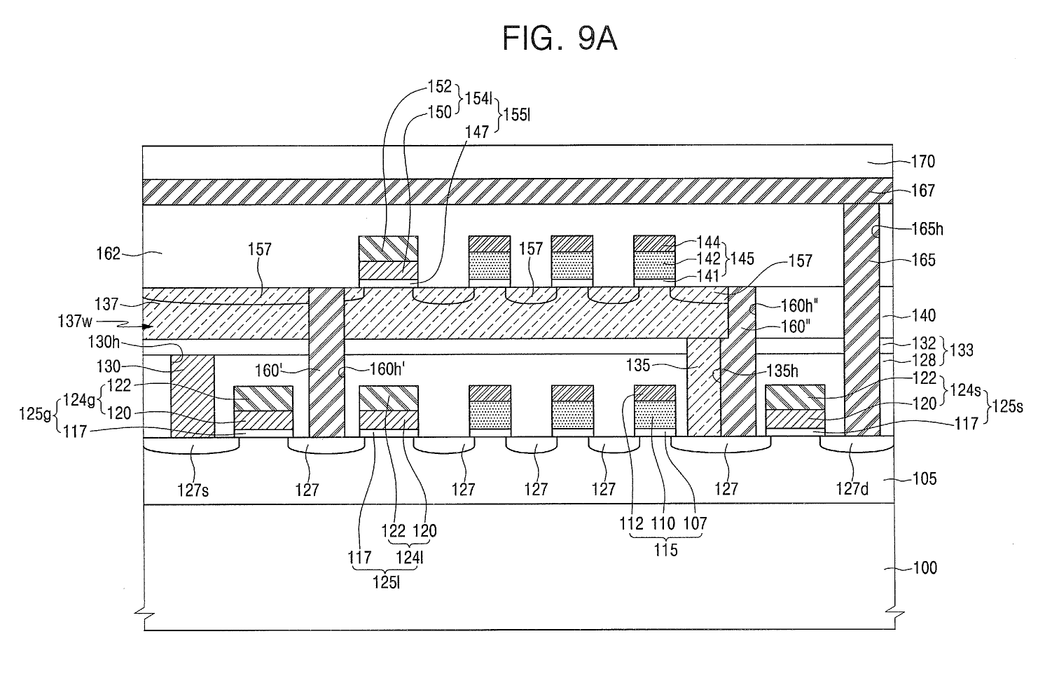

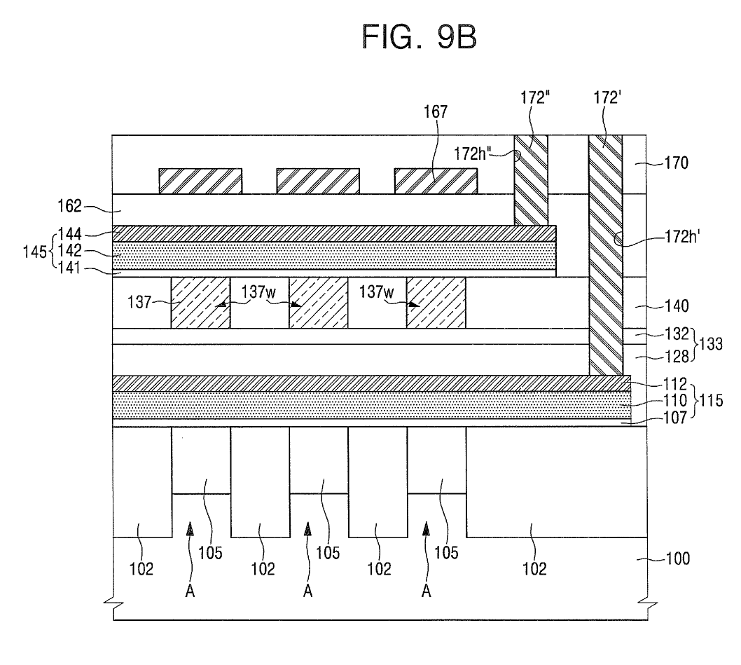

Referring to FIGS. 3, 9A, and 9B, an intermetal insulating layer 170 may be formed on the substrate having the bit lines 167. The intermetal insulating layer 170, the upper interlayer insulating layer 162, the isolation pattern 140, and the lower interlayer insulating layer 133 may be sequentially patterned to form first word line contact holes 172h′, which expose the respective first word lines 112 of the first cell gates 115. At the same time, the intermetal insulating layer 170 and the upper interlayer insulating layer 162 may be sequentially patterned to form second word line contact holes 172h″, which expose the respective second word lines 144 of the second cell gates 145. First and second word line contact plugs 172′ and 172″, which respectively fill the first and second word line contact holes 172h′ and 172h″, may be formed.

As described above, the cell transistors are formed as one transistor type NDRO-FRAM cells to use the ferroelectric patterns 110 and 142 as information storage elements of the flash memory device. Accordingly, programming may be implemented with low power compared to the conventional NAND type flash memory device using a floating gate as an information storage element. In addition, integration density may be enhanced by stacking the cell transistors.

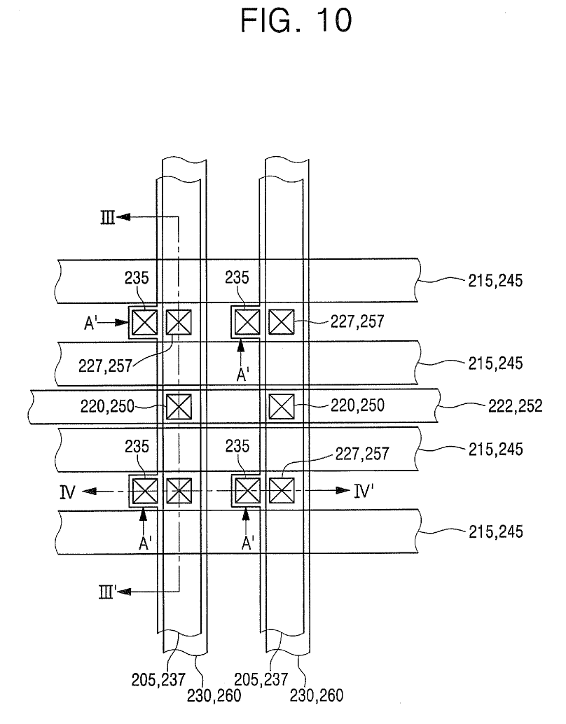

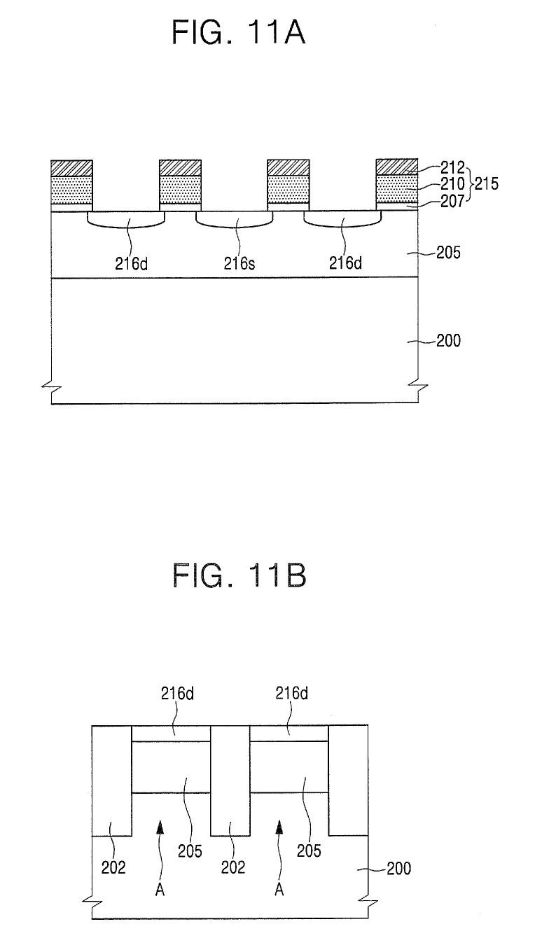

FIG. 10 is a plan view of a flash memory device in accordance with other exemplary embodiments of the present invention, FIGS. 11A, 12A, 13A, and 14A are cross-sectional views of intermediate fabrication products generated in producing the flash memory device of FIG. 10 taken along line III-III′ of FIG. 10, and FIGS. 11B, 12B, 13B, and 14B are cross-sectional views taken along line IV-IV′ of FIG. 10.

Referring to FIGS. 10, 11A, and 11B, an isolation layer 202 is formed to define a plurality of active regions A within a semiconductor substrate 200. The semiconductor substrate 200 may be a silicon substrate or an SOI substrate. The active regions A may have line shapes. In some embodiments, the active regions A may have line shapes having protrusions A′. The isolation layer 202 may be formed by a shallow trench isolation process. Impurity ions may be implanted into the semiconductor substrate using the isolation layer 202 as an ion implantation mask to form first line-shaped wells 205 within the active regions A. The first line-shaped wells 205 are separated by the isolation layer 202 so that voltage may be independently applied to the first line-shaped wells 205. The first line-shaped wells 205 may be a p-type.

In some embodiments, a preliminary well may be formed within a cell region of the semiconductor substrate 200 prior to the formation of the isolation layer 202. Subsequently, the isolation layer 202 may be formed deeper than the preliminary well. As a result, the first line-shaped wells 205 separated by the isolation layer 202 may be formed, and a voltage may be independently applied to the first line-shaped wells 205.

First cell gates 215 crossing the active regions A are formed on the substrate having the first line-shaped wells 205. Each of the first cell gates 215 may include an interfacial insulating layer pattern 207, a ferroelectric pattern 210, and a first word line 212, which are stacked. The interfacial insulating layer pattern 207 may be omitted and/or a lower electrode (not shown) may be interposed between the interfacial insulating layer pattern 207 and the ferroelectric pattern 210.

The interfacial insulating layer pattern 207 may include a high-k dielectric layer. The interfacial insulating layer pattern 207 may include Al₂O₃, HfO₂, HfAlOₓ, SrTiO, ZrO₂, Ta₂O₅, and/or TiO₂. The ferroelectric pattern 210 may include a lead zirconate titanate layer (PbZrₓTi₁₋ₓO₃; PZT), a bismuth lanthanum titanate layer (Bi₄₋ₓLaₓTi₃O₁₂; BLT), a strontium bismuth tantalite layer (SrBi₂Ta₂O₅; SBT), and/or a lead germanium oxide layer (Pb₅Ge₅O₁₁; PGO). The first word line 212 may include Pt, Ru, Ir, and/or IrO₂.

Impurity ions may be implanted into the substrate using the first cell gates 215 as ion implantation masks to form first source regions 216s and first drain regions 216d. The first cell gates 215 overlapping the respective active regions A, and the first source regions 216s and the first drain regions 216d adjacent to the first cell gates 215 may constitute first cell transistors.

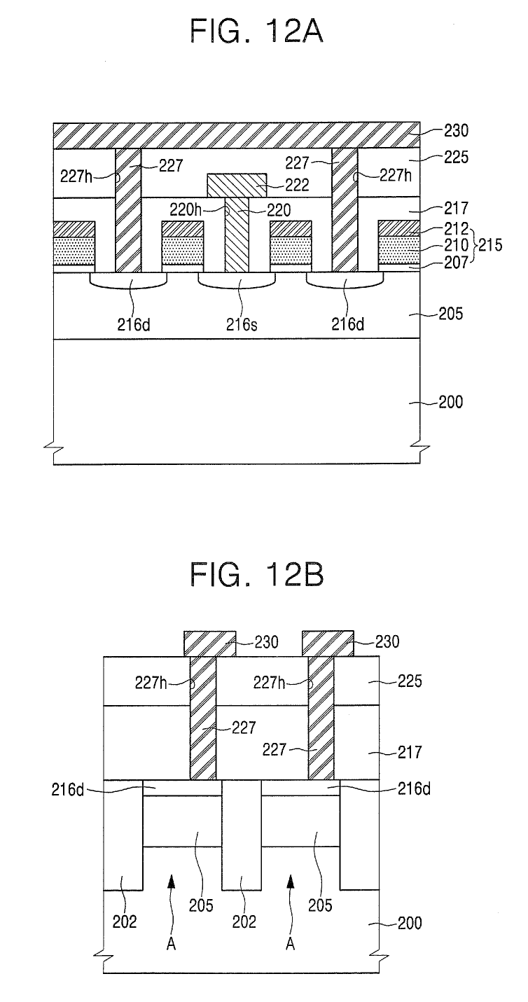

Referring to FIGS. 10, 12A, and 12B, a first lower interlayer insulating layer 217 may be formed on the substrate having the first cell transistors, and the first lower interlayer insulating layer 217 may be patterned to form first source contact holes 220h exposing the first source regions 216s. Subsequently, a conductive layer may be formed to fill the first source contact holes 220h and cover the first lower interlayer insulating layer 217. The conductive layer may be patterned to form the first source contact plugs 220 and to simultaneously form first common source lines 222 covering the first source contact plugs 220 and running in a direction parallel to the first cell gates 215.

A second lower interlayer insulating layer 225 may be formed on the first lower interlayer insulating layer 217. The second and first lower interlayer insulating layers 225 and 217 may be sequentially patterned to form first drain contact holes 227h exposing the first drain regions 216d. Subsequently, a conductive layer may be formed to fill the first drain contact holes 227h and cover the second lower interlayer insulating layer 225. The conductive layer may be patterned to form the first drain contact plugs 227 and to simultaneously form first bit lines 230 covering the first drain contact plugs 227 and running in a direction parallel to the active regions A.

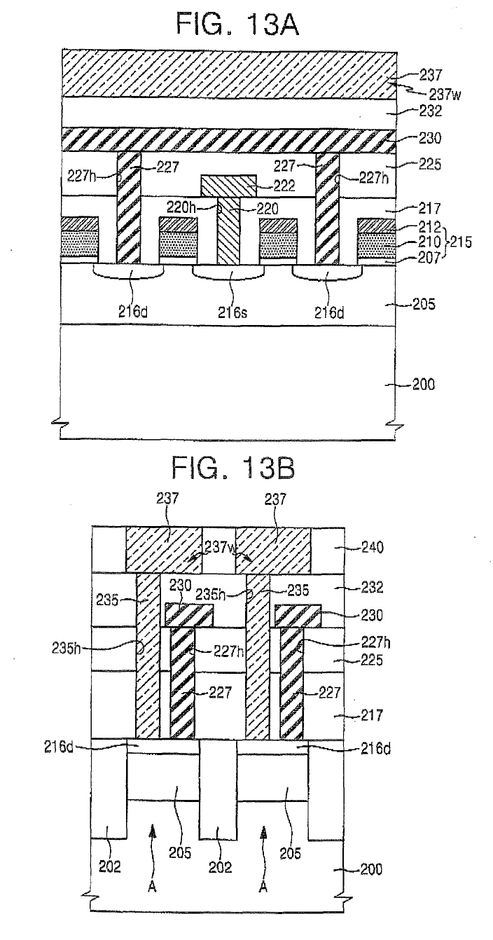

Referring to FIGS. 10, 13A, and 13B, a layer isolation insulating layer 232 may be formed on the substrate having the first bit lines 230. The layer isolation insulating layer 232, the second lower interlayer insulating layer 225, and the first lower interlayer insulating layer 217 may be sequentially patterned to form contact holes 235h exposing the first drain regions 216d. The contact holes 235h may be formed in the protrusions A′ of the active regions. Subsequently, a single crystalline layer filling the contact holes 235h may be formed by a single crystalline growth method, and the single crystalline layer may be planarized until the layer isolation insulating layer 232 is exposed to form a single crystalline contact plug 235 within the contact hole 235h. A non-single crystalline semiconductor layer may be formed on the substrate having the single crystalline contact plug 235. Subsequently, the non-single crystalline semiconductor layer may be formed into a single crystalline semiconductor layer by an SPE process or a laser annealing process. The single crystalline semiconductor layer may be patterned to form line-shaped semiconductor body patterns 237 parallel to the active regions A.

In some exemplary embodiments of the present invention, after the contact holes 235h exposing the first drain regions 216d are formed, a single crystalline layer may be formed by a single crystalline growth method, which fills the contact holes 235h and covers the layer isolation insulating layer 232. The single crystalline layer may be partially planarized to form single crystalline contact plugs 235 filling the contact holes 235h and to simultaneously form a single crystalline semiconductor layer on the layer isolation insulating layer 232. Subsequently, the single crystalline semiconductor layer may be patterned to form line-shaped semiconductor body patterns 237 parallel to the active regions A.

After an insulating layer is formed on the substrate having the line-shaped semiconductor body patterns 237, the insulating layer is planarized until the line-shaped semiconductor body patterns 237 are exposed. As a result, an upper isolation pattern 240 filling between the line-shaped semiconductor body patterns 237 may be formed. The upper isolation pattern 240 may include a silicon oxide layer.

In other exemplary embodiments, the single crystalline layer may be planarized until the layer isolation insulating layer 232 is exposed to form single crystalline contact plugs 235 within the contact holes 235h, and then an insulating layer may be formed on the substrate having the single crystalline contact plugs 235. Subsequently, the insulating layer may be patterned to form an upper isolation pattern 240 having line-shaped openings in a direction parallel to the active regions A. The openings expose the single crystalline contact plugs 235. Subsequently, the single crystalline growth method may be performed using the single crystalline contact plug 235 as a seed layer so that a single crystalline semiconductor layer filling the openings may be formed. The single crystalline semiconductor layer may be planarized until the upper isolation pattern 240 is exposed to form line-shaped semiconductor body patterns 237. As such, when the upper isolation pattern 240 is formed in advance and the single crystalline growth method is employed to form the single crystalline semiconductor layer, it is not necessary to grow the single crystalline semiconductor layer over an unnecessary region, so that a process time of the single crystalline growth may be reduced.

Impurity ions may be implanted into the substrate having the line-shaped semiconductor body patterns 237 to form second line-shaped wells 237w within the line-shaped semiconductor body patterns 237. The second line-shaped wells 237w may be a p-type. The second line-shaped wells 237w may be formed within the entire line-shaped semiconductor body patterns 237.

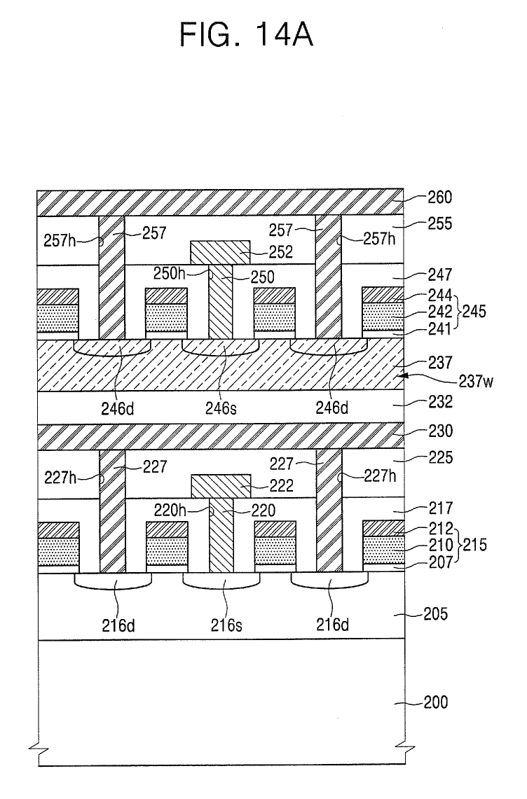

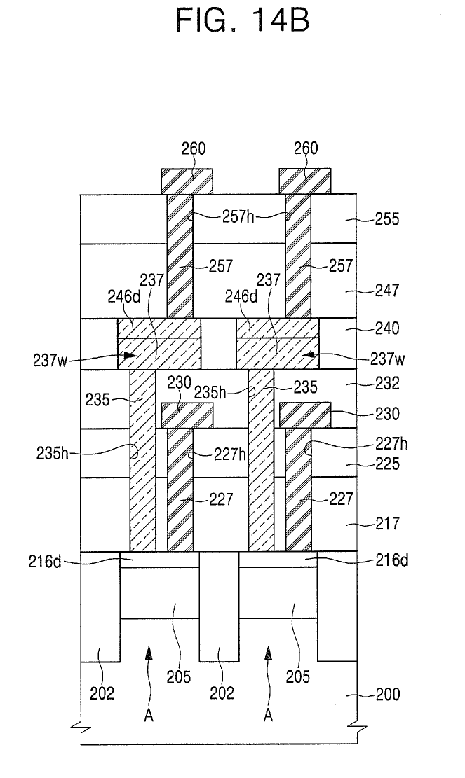

Referring to FIGS. 10, 14A, and 14B, second cell gates 245 crossing the line-shaped semiconductor body patterns 237 may be formed on the substrate having the line-shaped semiconductor body patterns 237. The second cell gates 245 may be parallel to the first cell gates 215, and may be formed over the first cell gates 215. Each of the second cell gates 245 may include an interfacial insulating layer pattern 241, a ferroelectric pattern 242, and a second word line 244, which are stacked. The interfacial insulating layer pattern 241 may be omitted and/or a lower electrode (not shown) may be interposed between the interfacial insulating layer pattern 241 and the ferroelectric pattern 242. The second cell gates 245 may have the same stacked structure as the first cell gates 215 and may include the same material layer as the first cell gates 215.

Impurity ions may be implanted into the semiconductor body patterns 237 using the second cell gates 245 as ion implantation masks to form second source regions 246s and second drain regions 246d. The second cell gates 245 overlapping the semiconductor body patterns 237, and the second source regions 246s and the second drain regions 246d adjacent to the second cell gates 245 may constitute second cell transistors.

A first upper interlayer insulating layer 247 may be formed on the substrate having the second cell transistors, and then patterned to form second source contact holes 250h exposing the second source regions 246s. Subsequently, a conductive layer may be formed, which fills the second source contact holes 250h and covers the first upper interlayer insulating layer 247. The conductive layer may be patterned to form the second source contact plugs 250 and to simultaneously form second common source lines 252 covering the second source contact plugs 250 and running in a direction parallel to the second cell gates 245.

A second upper interlayer insulating layer 255 may be formed on the first upper interlayer insulating layer 247. The second and first upper interlayer insulating layers 255 and 247 may be sequentially patterned to form second drain contact holes 257h exposing the second drain regions 246d. Subsequently, a conductive layer may be formed, which fills the second drain contact holes 257h and covers the second upper interlayer insulating layer 255. The conductive layer may be patterned to form the second drain contact plugs 257 and to simultaneously form second bit lines 260 covering the second drain contact plugs 257 and running in a direction parallel to the line-shaped semiconductor body patterns 237.

Subsequently, the same processes as the processes of FIGS. 13A, 13B, 14A, and 14B may be repeatedly performed to further form semiconductor body patterns (not shown) and cell gates (not shown) by a desired amount. Accordingly, integration density may be enhanced within the same area. In some embodiments, the processes of FIGS. 13A, 13B, 14A, and 14B may be skipped to form a memory device having a single layer structure.

A flash memory device according to exemplary embodiments of the present invention will now be described with reference to FIGS. 3, 9A, and 9B again.

Referring to FIGS. 3, 9A, and 9B, an isolation layer 102 is disposed to define a plurality of active regions A within a semiconductor substrate 100. The semiconductor substrate 100 may be a silicon substrate or an SOI substrate. The active regions A may have line shapes. First line-shaped wells 105, which are separated by the isolation layer 102, may be disposed within the active regions A. Since the first line-shaped wells 105 are separated by the isolation layer 102, a voltage may be independently applied to the first line-shaped wells 105.

First cell gates 115 crossing the active regions A are disposed on the substrate having the first line-shaped wells 105. Each of the first cell gates 115 may include an interfacial insulating layer pattern 107, a ferroelectric pattern 110, and a first word line 112, which are stacked. The interfacial insulating layer pattern 107 may be omitted and/or a lower electrode (not shown) may be interposed between the interfacial insulating layer pattern 107 and the ferroelectric pattern 110.

The interfacial insulating layer pattern 107 may be a high-k dielectric layer. The interfacial insulating layer pattern 107 may include one material layer selected from the group consisting of Al₂O₃, HfO₂, HfAlOₓ, SrTiO, ZrO₂, Ta₂O₅, and TiO₂. The ferroelectric pattern 110 may include a lead zirconate titanate layer (PbZrₓTi₁₋ₓO₃; PZT), a bismuth lanthanum titanate layer (Bi₄₋ₓLaₓTi₃O₁₂; BLT), a strontium bismuth tantalite layer (SrBi₂Ta₂O₅; SBT), and/or a lead germanium oxide layer (Pb₅Ge₅O₁₁; PGO). The first word line 112 may include Pt, Ru, Ir, and/or IrO₂.

A string select gate 125s, a ground select gate 125g, and a first layer select gate 125l, which are parallel to the first cell gates 115 and cross the active regions A, may be disposed on the substrate having the first cell gates 115. The first layer select gate 125l may be disposed between the ground select gate 125g and the first cell gate 115.

The string select gate 125s may include a gate insulating layer pattern 117 and a string select gate electrode 124s which are stacked. The ground select gate 125g may include a gate insulating layer pattern 117 and a ground select gate electrode 124g which are stacked. The first layer select gate 125l may include a gate insulating layer pattern 117 and a first layer select gate electrode 124l, which are stacked.

The gate insulating layer pattern 117 may be a high-k dielectric layer or a silicon oxide layer. Each of the select gate electrodes 124s, 124g, and 124l may include a polysilicon pattern 120 and a metal silicide pattern 122 which are stacked. The metal silicide pattern 122 may be tungsten silicide, cobalt silicide and/or nickel silicide. In some embodiments, each of the select gate electrodes 124s, 124g, and 124l may include a polysilicon pattern. In some exemplary embodiments of the present invention, the select gates 125s, 125g, and 125l may have the same stacked structure as the first cell gates 115.

First source/drain regions 127 may be disposed within the active regions A adjacent to the first cell gates 115 and the select gates 125s, 125g, and 125l. The first source/drain regions 127 may be n-type impurity regions. The first cell gates 115 overlapping the respective active regions A, and the first source/drain regions 127 adjacent to the first cell gates 115 may constitute first cell transistors. The string select gate 125s overlapping the respective active regions A, and the first source/drain regions 127 adjacent to the string select gate 125s may constitute a string select transistor. The ground select gate 125g overlapping the active regions A, and the first source/drain regions 127 adjacent to the ground select gate 125g may constitute a ground select transistor. The first layer select gate 125l overlapping the active regions A, and the first source/drain regions 127 adjacent to the first layer select gate 125l may constitute a first layer select transistor.

Active regions adjacent to the string select gate 125s and disposed opposite to the first cell gates 115 may be defined as drain regions 127d of the respective string select transistors. Active regions adjacent to the ground select gate 125g and disposed opposite to the first cell gates 115 may be defined as source regions 127s of the respective ground select transistors.

A first lower interlayer insulating layer 128 may be disposed on the substrate having the gates 115, 125s, 125g, and 125l. The first lower interlayer insulating layer 128 may be a silicon oxide layer. A common source line trench 130h is penetrates the first lower interlayer insulating layer 128, exposes the source regions 127s of the ground select transistors, and extends in a direction parallel to the ground select gate 125g. A common source line 130 fills the common source line trench 130h. The common source line 130 may be a polysilicon layer, a tungsten layer, an aluminum layer and/or a stacked layer of a polysilicon layer and a tungsten layer.

A second lower interlayer insulating layer 132 is disposed on the substrate having the common source line 130. The first and second lower interlayer insulating layers 128 and 132 may constitute a lower interlayer insulating layer 133. Contact holes 135h may be disposed, which penetrate the lower interlayer insulating layer 133 and expose the respective first source/drain regions 127 between the first cell gate 115 and the string select gate 125s. Single crystalline contact plugs 135 may be disposed within the contact holes 135h, respectively. Line-shaped semiconductor body patterns 137, which cover the single crystalline contact plugs 135, may be disposed on the substrate having the single crystalline contact plugs 135 in a direction parallel to the active regions A. The semiconductor body patterns 137 are preferably not disposed over the string select gate 125s.

An upper isolation pattern 140 fills between the line-shaped semiconductor body patterns 137. The upper isolation pattern 140 may be a silicon oxide layer. First line-shaped wells 137w may be disposed within the line-shaped semiconductor body patterns 137. The first line-shaped wells 137w may be a p-type. The first line-shaped wells 137w may be disposed within the entire line-shaped semiconductor body patterns 137.

Second cell gates 145 crossing the line-shaped semiconductor body patterns 137 may be disposed on the substrate having the line-shaped semiconductor body patterns 137. The second cell gates 145 may be parallel to the first cell gates 115, and may be disposed over the first cell gates 115. Each of the second cell gates 145 may include an interfacial insulating layer pattern 141, a ferroelectric pattern 142, and a second word line 144, which are stacked. The interfacial insulating layer pattern 141 may be omitted and/or a lower electrode (not shown) may be interposed between the interfacial insulating layer pattern 141 and the ferroelectric pattern 142. The second cell gates 145 may have the same stacked structure as the first cell gates 115 and may be the same material layer as the first cell gates.

A second layer select gate 155l may be disposed on the substrate having the second cell gates 145. The second layer select gate 155l may be disposed over the first layer select gate 125l. The second layer select gate 155l may include a gate insulating layer pattern 147 and a second layer select gate electrode 154l, which are stacked. The gate insulating layer pattern 147 may be a high-k dielectric layer or a silicon oxide layer. The second layer select gate electrode 154l may include a polysilicon pattern 150 and a metal silicide pattern 152, which are stacked. The metal silicide pattern 152 may be tungsten silicide, cobalt silicide and/or nickel silicide. In some embodiments, the second layer select gate electrode 154l may be a polysilicon pattern. In some exemplary embodiments of the present invention, the second layer select gate 155l may have the same stacked structure as the second cell gates 145.

Second source/drain regions 157 may be disposed within the line-shaped semiconductor body pattern 137 adjacent to the second cell gates 145 and the second layer select gate 155l. The second source/drain regions 157 may be n-type impurity regions. The second cell gates 145 overlapping the respective line-shaped semiconductor body patterns 137, and the second source/drain regions 157 adjacent to the second cell gates 145 may constitute second cell transistors. The second layer select gate 155l overlapping the line-shaped semiconductor body patterns 137, and the second source/drain regions 157 adjacent to the second layer select gate 155l may constitute second layer select transistors.

Semiconductor body pattern layers (not shown), cell gates (not shown), and layer select gates (not shown), which have the same structures as the respective semiconductor body pattern 137, the second cell gates 145, and the second layer select gate 155l, may be further disposed on the substrate having the second cell gates 145 and the second layer select gate 155l. In some embodiments, the semiconductor body pattern 137, the second cell gates 145, and the second layer select gate 155l may be omitted. That is, a single layer structure may be implemented.

First contact holes 160h′ may penetrate the semiconductor body pattern 137 and the lower interlayer insulating layer 133 and expose the first source/drain regions 127 between the first layer select gate 125l and the ground select gate 125g. The first contact holes 160h′ expose sidewalls of the semiconductor body patterns 137. In particular, the second source/drain regions 157 are preferably exposed to the sidewalls. Each diameter of the first contact holes 160h′ is preferably smaller than each width of the corresponding semiconductor body patterns 137. In addition, Second contact holes 160h″ may be disposed, which sequentially penetrate the upper isolation pattern 140 and the lower interlayer insulating layer 133 to expose sidewalls of the semiconductor body patterns 137 while exposing the first source/drain regions 127 between the first cell gate 115 and the string select gate 125s.

First and second contact plugs 160′ and 160″ may fill the respective first and second contact holes 160h′ and 160h″. The first and second contact plugs 160′ and 160″ may be polysilicon having the same conductivity type as that of the first and second source/drain regions 127 and 157. For example, the first and second contact plugs 160′ and 160″ may be n-type polysilicon.

The second source/drain regions 157 may be electrically connected to the first source/drain regions 127 by the first and second contact plugs 160′ and 160h″. Specifically, the first contact plugs 160′ may electrically connect the source regions 127 and 157 adjacent to the first and second layer select gates 125l and 155l to each other, and the second contact plugs 160″ may electrically connect the drain regions 127 and 157 of the first and second cell gates 115 and 145 adjacent to the string select gate 125s.

An upper interlayer insulating layer 162 may be disposed on the substrate having the second cell gates 145 and the second layer select gate 155l. Bit line contact holes 165h may penetrate the upper interlayer insulating layer 162, the isolation pattern 140, and the lower interlayer insulating layer 133 and expose the respective drain regions 127d adjacent to the string select gate 125s. Bit line contact plugs 165 may fill the bit line contact holes 165h, and bit lines 167 covering the bit line contact plugs 165 and extending in a direction parallel to the active regions A.

An intermetal insulating layer 170 may be disposed on the substrate having the bit lines 167. First word line contact holes 172h′ may penetrate the intermetal insulating layer 170, the upper interlayer insulating layer 162, the isolation pattern 140, and the lower interlayer insulating layer 133 and expose the respective first word lines 112 of the first cell gates 115. Second word line contact holes 172h″ may penetrate the intermetal insulating layer 170 and the upper interlayer insulating layer 162 and expose the respective second word lines 144 of the second cell gates 145. First and second word line contact plugs 172′ and 172″ may fill the respective first and second word line contact holes 172h′ and 172h″. A voltage may be independently applied to each of the first and second word lines 112 and 144 by means of the first and second word line contact plugs 172′ and 172″.

A flash memory device according to other exemplary embodiments of the present invention will now be described with reference to FIGS. 10, 14A, and 14B again.

Referring to FIGS. 10, 14A, and 14B, an isolation layer 202 defines a plurality of active regions A within a semiconductor substrate 200. The semiconductor substrate 200 may be a silicon substrate or an SOI substrate. The active regions A may have line shapes. In some embodiments, the active regions A may have line shapes having protrusions A′. First line-shaped wells 205 separated by the isolation layer 202 may be disposed within the active regions A. Since the first line-shaped wells 205 are separated by the isolation layer 202, a voltage may be independently applied to the first line-shaped wells 205.

First cell gates 215 crossing the active regions A are disposed on the substrate having the first line-shaped wells 205. Each of the first cell gates 215 may include an interfacial insulating layer pattern 207, a ferroelectric pattern 210, and a first word line 212, which are stacked. The interfacial insulating layer pattern 207 may be omitted and/or a lower electrode (not shown) may be interposed between the interfacial insulating layer pattern 207 and the ferroelectric pattern 210.

The interfacial insulating layer pattern 207 may be a high-k dielectric layer. The interfacial insulating layer pattern 207 may include Al₂O₃, HfO₂, HfAlOₓ, SrTiO, ZrO₂, Ta₂O₅, and/or TiO₂. The ferroelectric pattern 210 may include a lead zirconate titanate layer (PbZrₓTi₁₋ₓO₃; PZT), a bismuth lanthanum titanate layer (Bi₄₋ₓLaₓTi₃O₁₂; BLT), a strontium bismuth tantalite layer (SrBi₂Ta₂O₅; SBT) and/or a lead germanium oxide layer (Pb₅Ge₅O₁₁; PGO). The first word line 212 may include Pt, Ru, Ir and/or IrO₂.

First source regions 216s and first drain regions 216d may be disposed within the active regions A adjacent to the first cell gates 215. The first cell gates 215 overlapping the active regions A, and the first source regions 216s and the first drain regions 216d adjacent to the first cell gates 215 may constitute first cell transistors.

A first lower interlayer insulating layer 217 may be disposed on the substrate having the first cell transistors. First source contact holes 220h may penetrate the first lower interlayer insulating layer 217 and expose the first source regions 216s. First source contact plugs 220 may fill the first source contact holes 220h. First common source lines 222 may be disposed on the first lower interlayer insulating layer 217, which cover the first source contact plugs 220 and extend in a direction parallel to the first cell gates 215.

A second lower interlayer insulating layer 225 may be disposed on the first lower interlayer insulating layer 217. First drain contact holes 227h may penetrate the second and first lower interlayer insulating layers 225 and 217 and expose the first drain regions 216d. The first drain contact plugs 227 may fill the first drain holes 227h. First bit lines 230 may be disposed on the second lower interlayer insulating layer 225, which cover the first drain contact plugs 227 and extend in a direction parallel to the active regions A.

A layer isolation insulating layer 232 may be disposed on the substrate having the first bit lines 230. Contact holes 235h may penetrate the layer isolation insulating layer 232, and the second and first lower interlayer insulating layers 225 and 217 and expose the first drain regions 216d. The contact holes 235h may be disposed in the protrusions A′ of the active regions. Single crystalline contact plugs 235 may fill the contact holes 235h. Line-shaped semiconductor body patterns 237 may be disposed on the substrate having the single crystalline contact plugs 235, which cover the single crystalline contact plugs 235 and extend parallel to the active regions A.

An upper isolation pattern 240 filling between the line-shaped semiconductor body patterns 237 may be disposed on the substrate having the line-shaped semiconductor body patterns 237. The upper isolation pattern 240 may be a silicon oxide layer. Second line-shaped wells 237w may be disposed within the line-shaped semiconductor body patterns 237. The second line-shaped wells 237w may be a p-type. The second line-shaped wells 237w may be disposed within the entire line-shaped semiconductor body patterns 237.

Second cell gates 245 crossing the line-shaped semiconductor body patterns 237 may be disposed on the substrate having the line-shaped semiconductor body patterns 237. The second cell gates 245 may be parallel to the first gates 215, and may be disposed over the first gates 215. Each of the second cell gates 245 may include an interfacial insulating layer pattern 241, a ferroelectric pattern 242, and a second word line 244, which are stacked. The interfacial insulating layer pattern 241 may be omitted and/or a lower electrode (not shown) may be interposed between the interfacial insulating layer pattern 241 and the ferroelectric pattern 242. The second cell gates 245 may have the same stacked structure as the first cell gates 215 and may be the same material layer as the first cell gates 215.

Second source regions 246s and second drain regions 246d may be disposed within the semiconductor body patterns 237 adjacent to the second cell gates 245. The second cell gates 245 overlapping the semiconductor body patterns 237, and the second source regions 246s and the second drain regions 246d adjacent to the second cell gates 245 may constitute second cell transistors.

A first upper interlayer insulating layer 247 may be disposed on the substrate having the second cell transistors. Second source contact holes 250h may penetrate the first upper interlayer insulating layer 247 and expose the second source regions 246s. Second source contact plugs 250 may fill the second source contact holes 250h. Second common source lines 252 may be disposed on the first upper interlayer insulating layer 247, which cover the second source contact plugs 250 and extend in a direction parallel to the second cell gates 245.

A second upper interlayer insulating layer 255 may be disposed on the substrate having the first upper interlayer insulating layer 247. Second drain contact holes 257h may penetrate the second and first upper interlayer insulating layers 255 and 247 and expose the second drain regions 246d. Second drain contact plugs 257 may fill the second drain contact holes 257h. Second bit lines 260 may be disposed on the second upper interlayer insulating layer 255, which cover the second drain contact plugs 257 and extend in a direction parallel to the line-shaped semiconductor body patterns 237.

Semiconductor body pattern layers (not shown), cell gates (not shown), common source lines (not shown), and bit lines (not shown), which have the same structures as the respective semiconductor body pattern 237, the second cell gates 245, the second common source lines 252, and the second bit lines 260, may be further disposed on the substrate having the second bit lines 260. The integration density of the cells may be enhanced within the same area by the stacked structure. In some embodiments, the semiconductor body pattern 137, the second cell gates 245, the second common source lines 252, and the second bit lines 260 may be omitted. That is, a single layer structure may be implemented.

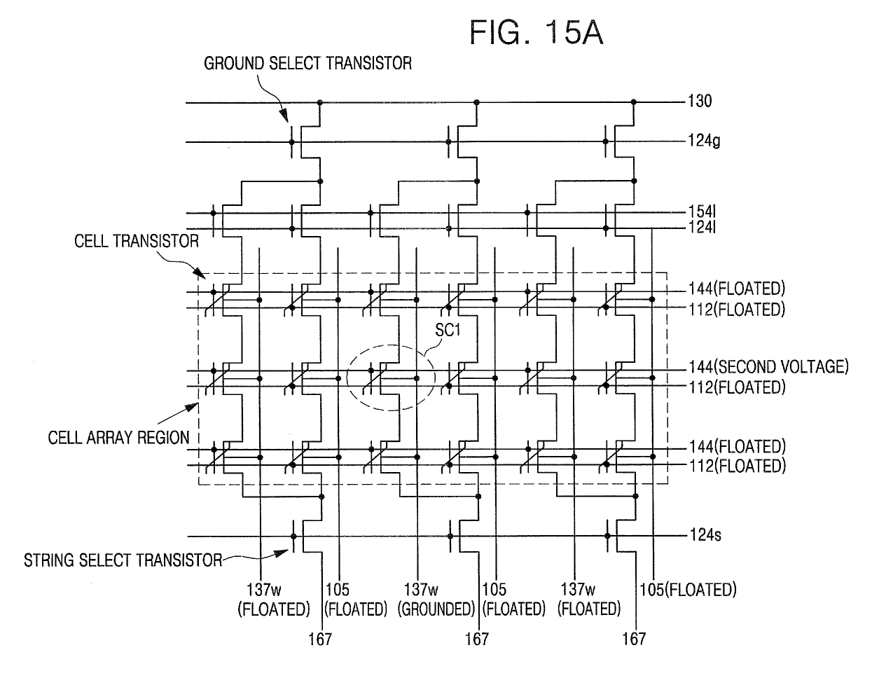

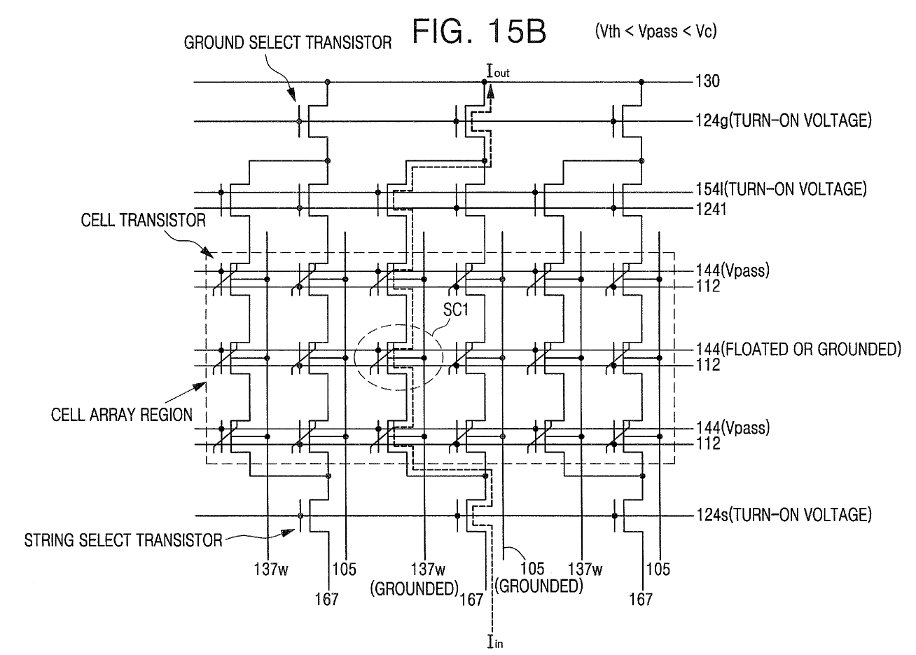

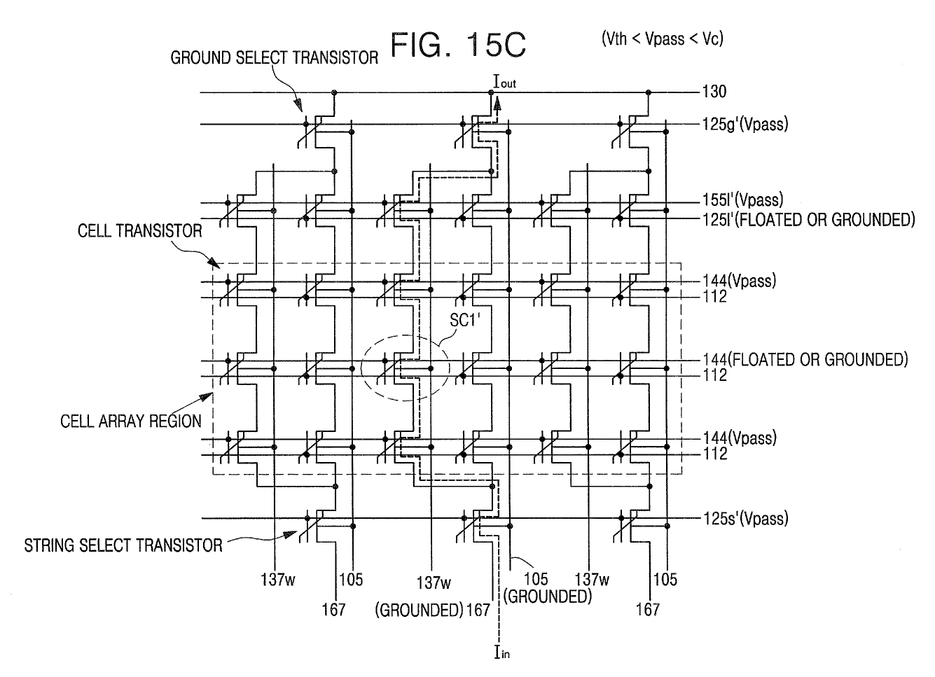

FIG. 15A is a circuit diagram illustrating exemplary write operations for a flash memory device in accordance with some embodiments of the present invention shown in FIGS. 3, 9A, and 9B. In particular, FIG. 15A illustrates the state when data is written to an arbitrarily selected cell SC1.

Referring to FIGS. 3, 9A, 9B, and 15A, a first voltage is applied to one type of wells selected from between first line-shaped wells 105 disposed within the semiconductor substrate 100 and second line-shaped wells 137w disposed within semiconductor body patterns 137, and the non-selected wells are floated. A second voltage is applied to one selected between first and second word lines 112 and 144 to polarize a ferroelectric pattern interposed between the selected word line and the selected well. In this case, the non-selected word lines among the first and second word lines 112 and 144 are floated. First and second source/drain regions 127 and 157 adjacent to the first and second word lines 112 and 144 may be floated or grounded.

In some embodiments, the first voltage may be a ground voltage, and the second voltage may be a +Vcc voltage higher than the first voltage. In other embodiments, the first voltage may be a −Vcc voltage, and the second voltage may be a ground voltage. As such, when the second voltage is higher than the first voltage by Vcc, the ferroelectric patterns 110 and 142 are subjected to polarization to have a state of “1”, and negative charges are induced below the ferroelectric patterns 110 and 142 so that a channel is formed.

In some embodiments, the first voltage may be a ground voltage, and the second voltage may be a −Vcc voltage lower than the first voltage. In other embodiments, the first voltage may be a +Vcc voltage, and the second voltage may be a ground voltage. As such, when the first voltage is higher than the second voltage by Vcc, the ferroelectric patterns 110 and 142 are subjected to polarization to have a state of “0”, and positive charges are induced below the ferroelectric patterns 110 and 142 to interrupt the channel from being formed.

In some exemplary embodiments of the present invention, data may be written to the flash memory device on a string basis or a word line basis. For a string unit basis, a ground voltage is applied to one type of wells selected from between the first line-shaped wells 105 disposed within the semiconductor substrate 100 and the second line-shaped wells 137w disposed within the semiconductor body patterns 137, and the non-selected wells are floated. A +Vcc voltage is applied to the word lines electrically connected to the respective cells where data “1” need to be written, and a −Vcc voltage is applied to the word lines electrically connected to the respective cells where data “0” need to be written. First and second source/drain regions 127 and 157 adjacent to the first and second word lines 112 and 144 may be floated or grounded.

In some embodiments, for a word line basis, the first word lines 112 or the second word lines 144 are grounded, and the non-selected word lines are floated. A −Vcc voltage is applied to the wells electrically connected to the respective cells where data I″ need to be written between the first line-shaped wells 105 disposed within the semiconductor substrate 100 and the second line-shaped wells 137w disposed within the semiconductor body patterns 137, and a +Vcc voltage is applied to the wells electrically connected to the respective cells where data “0” need to be written between the first and second line-shaped wells 105 and 137w. The first and second source/drain regions 127 and 157 adjacent to the first and second word lines 112 and 144 may be floated or grounded.

In some embodiments, erase and write operations similar to those applied to conventional NAND type flash memory devices may be applied to the flash memory device according to the exemplary embodiments of the present invention. That is, after the first and second cell transistors are erased to have the polarization state of data “0”, the selected bit line is grounded, and a Vcc is applied to the non-selected bit lines. In addition, a Vcc voltage is applied to the selected word line, and a pass voltage Vpass is applied to the non-selected word lines. As a result, source/drain regions of the string electrically connected to the selected bit line, and channels formed therebetween are grounded, so that a voltage difference of Vcc occurs between the selected word line and the channel therebelow to polarize the ferroelectric pattern of the select cell.

FIG. 15B is a circuit diagram illustrating exemplary read operations for a flash memory device in accordance with further embodiments of the present invention shown in FIGS. 3, 9A, and 9B. In particular, FIG. 15B illustrates a state when data of an arbitrarily selected cell SC1 is read.

Referring to FIGS. 3, 9A, 9B, and 15B, first and second line-shaped wells 105 and 137w, which are disposed within a semiconductor substrate 100 and a semiconductor body pattern 137 disposed over the semiconductor substrate 100, respectively, are grounded. A turn-on voltage is applied to a ground select gate electrode 124g and a string select gate electrode 124s crossing the first line-shaped wells 105. A turn-on voltage is applied to one of a first layer select gate electrode 124l and a second layer select gate electrode 154l.

A selected word line of the first and second word lines 112 and 144 is floated or grounded, and a pass voltage Vpass is applied to the non-selected word lines between the first and second word lines 112 and 144. The pass voltage Vpass has a value smaller than the minimum voltage Vc for polarizing the ferroelectric patterns 110 and 142 and greater than the threshold voltage Vth for forming a channel. A read voltage is applied between the common source line 130 and the bit line 167 to sense a change in current of the bit line according to the polarization state of the ferroelectric pattern of the arbitrarily selected cell SC1.

In some exemplary embodiments of the present invention, data may be read on a word line basis. Data of all cells sharing the selected word line, i.e., the floated or grounded word line, may be simultaneously read via the respective bit lines 167.

FIG. 15C is a circuit diagram illustrating exemplary read operations for a flash memory device according to some embodiments of the present invention. As shown in FIG. 3, the flash memory device is configured to have a ferroelectric pattern composed of a string select gate 125s′, a ground select gate 125g′, and layer select gates 125l′ and 155l′ which are stacked, and a gate electrode. In particular, FIG. 15C shows a state when data of arbitrarily selected cell SC1′ is read.

Wells 105 and 137 of the string select gate 125s′, the ground select gate 15g′, and the layer select gates 125l′ and 155l′ are grounded in the writing operation, and a −Vcc voltage is applied to gate electrodes of the string select gate 125s′, the ground select gate 125g′, and the layer select gates 125l′ and 155l′ to turn off all channels of a ground select transistor, a string select transistor, and a layer select transistor.

With reference to FIGS. 3, 9A, 9B, and 15C, first and second line-shaped wells 105 and 137w, which are disposed within a semiconductor substrate 100 and a semiconductor body pattern 137 disposed over the semiconductor substrate, respectively, are grounded. A pass voltage Vpass is applied to gate electrodes of a ground select gate 125g′ and a string select gate 125s' crossing the first and second line-shaped wells 105 and 137w. A pass voltage is applied to a selected layer select gate of a first layer select gate 125l and a second layer select gate 155l, and a non-selected layer select gate is floated or grounded. The pass voltage Vpass has a value smaller than the minimum voltage Vc for polarizing the ferroelectric patterns 110 and 142 and greater than the threshold voltage Vth for forming the channel.

A selected word line of the first and second word lines 112 and 144 is floated or grounded, and a pass voltage Vpass is applied to non-selected word lines of the first and second word lines 112 and 144. A read voltage is applied between the common source line 130 and the bit line 167 to sense a change in current of the bit line according to the polarization state of the ferroelectric pattern of arbitrarily selected cell SC1′.

In some exemplary embodiments of the present invention, data may be read on a word line basis. That is, data of all cells sharing the floated or grounded word lines may be simultaneously read via the respective bit lines 167.

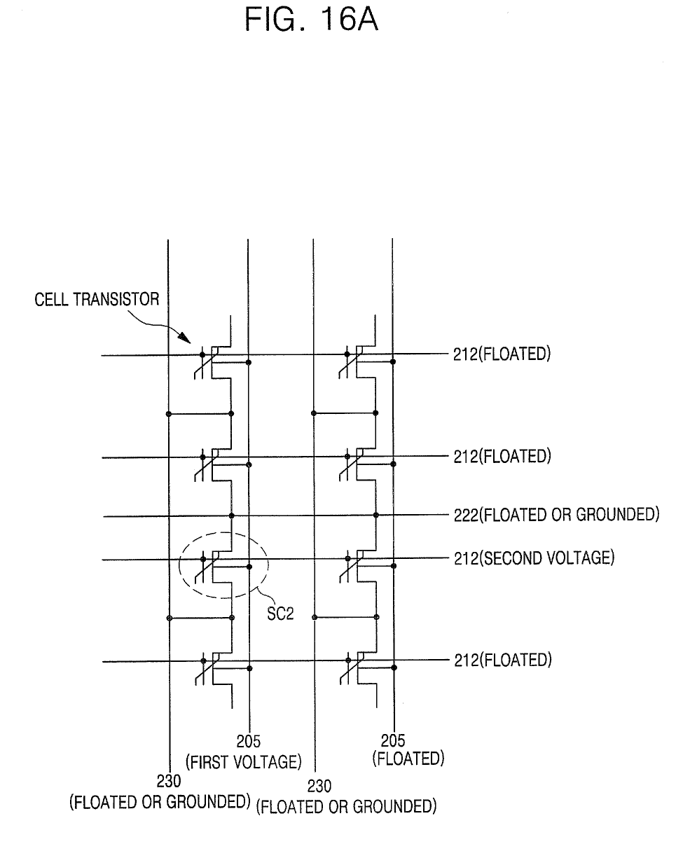

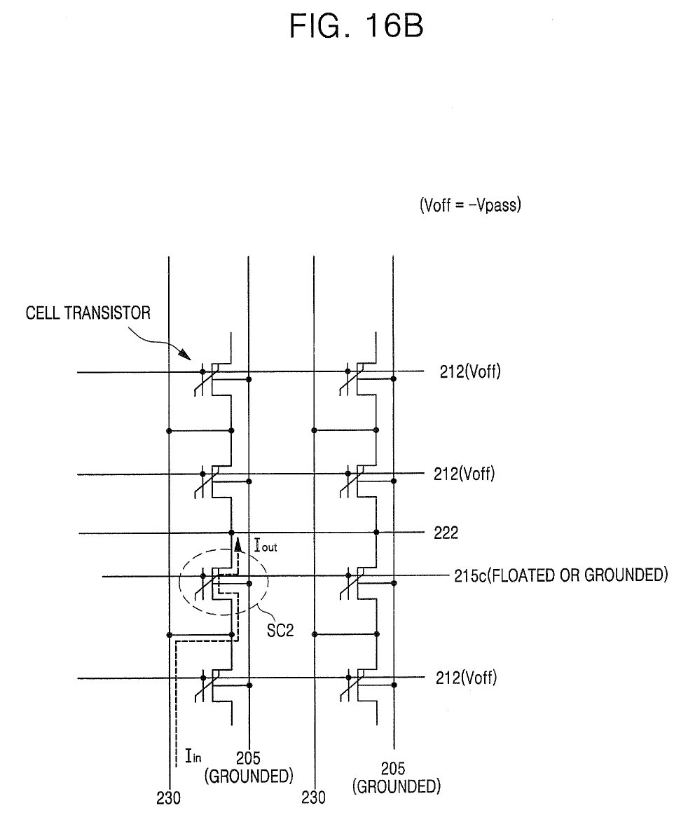

FIG. 16A is a circuit diagram illustrating exemplary write operations for a flash memory device according to further embodiments of the present invention, in particular, for the device shown in FIGS. 14A and 14B. FIG. 16A shows a circuit diagram for a single layer structure, but a stacked structure may use the same write operations as the single layer structure. In particular, FIG. 16A illustrates when data is written to an arbitrarily selected cell SC2.

Referring to FIGS. 10, 14A, 14B, and 16A, a first voltage is applied to a selected well among first line-shaped wells 205 disposed within a semiconductor substrate 200, and the non-selected wells are floated. A second voltage is applied to a selected line among first word lines 212 to polarize a ferroelectric pattern interposed between the selected word line and the selected well. In this case, the non-selected word lines among the first word lines 212 are floated. The common source line 222 connected to the source regions 216s, and the bit line 230 connected to the drain regions 216d are floated or grounded.

The first voltage may be a ground voltage, and the second voltage may be a +Vcc voltage higher than the first voltage. In some embodiments, the first voltage may be a −Vcc voltage, and the second voltage may be a ground voltage. As such, when the second voltage is higher than the first voltage by Vcc, the ferroelectric pattern 210 is subjected to polarization to have a state of “1”, and negative charges are induced below the ferroelectric pattern 210 so that a channel is formed.

In some embodiments, the first voltage may be a ground voltage, and the second voltage may be a −Vcc voltage lower than the first voltage. The first voltage may be a +Vcc voltage, and the second voltage may be a ground voltage. As such, when the first voltage is higher than the second voltage by Vcc, the ferroelectric pattern 210 is subjected to polarization to have a state of “0”, and positive charges are induced below the ferroelectric pattern 210 to interrupt the channel from being formed.

In some embodiments of the present invention, data may be written to the flash memory device on a string basis or a word line basis. For a string unit basis, a ground voltage is applied to a selected well among first line-shaped wells 205 disposed within a semiconductor substrate, and the non-selected wells are floated. A +Vcc voltage is applied to the word lines electrically connected to the respective cells where data “1” need to be written among the first word lines 212, and a −Vcc voltage is applied to the word lines electrically connected to the respective cells where data “0” need to be written among the first word lines 212. The common source line 222 connected to the source regions 216s, and the bit lines 230 connected to the drain regions 216d are floated or grounded.

In some embodiments, for a word line basis, a selected word line among the first word lines 212 is grounded, and the non-selected word lines are floated. A −Vcc voltage is applied to the wells electrically connected to the respective cells where data “1” need to be written among the first line-shaped wells 205 disposed within the substrate, and a +Vcc voltage is applied to the wells electrically connected to the respective cells where data “0” need to be written. The common source line 222 connected to the source regions 216s, and the bit lines 230 connected to the drain regions 216d are floated or grounded.

FIG. 16B is a circuit diagram illustrating exemplary read operations for a flash memory device according to some embodiments of the present invention, in particular, for a device as shown in FIGS. 10, 14A and 14B. FIG. 16B shows a circuit diagram for a single layer structure, but a stacked structure may use the same read operations. In particular, FIG. 16B illustrates a state when data is read to an arbitrarily selected cell SC2.

Referring to FIGS. 10, 14A, 14B, and 16B, first line-shaped wells 205 disposed within a semiconductor substrate 200 are grounded. A selected word line 212 among the word lines 212 is floated or grounded, and an off voltage Voff is applied to non selected word lines among the word lines 212. The off voltage Voff is a negative of the pass voltage described with reference to FIG. 15B. A read voltage is applied between the common source line 222 and the bit line 230 to sense a change in current of the bit line according to the polarization state of the ferroelectric pattern of the arbitrarily selected cell SC2.

In some exemplary embodiments of the present invention, data may be read on a word line basis. That is, data of all cells sharing the floated or grounded word line 212 may be simultaneously read via the respective bit lines 167.

According to exemplary embodiments of the present invention as described above, cell transistors of a flash memory device are formed as NDRO-FRAM cells to use ferroelectric patterns as information storage elements. Accordingly, programming may be implemented with low power compared to a conventional flash memory device using a floating gate as an information storage element. In addition, the structure of the cell transistors may lend itself to a stacked structure, so that integration density may be enhanced compared to conventional flash memory devices.

It will be apparent to those skilled in the art that various modifications and variations can be made in the present invention. Thus, it is intended that the present invention covers the modifications and variations of this invention provided they come within the scope of the appended claims and their equivalents.

What is claimed is:

1. A memory device comprising:
a layer of parallel strings of ferroelectric gate transistors on a substrate, the layer of parallel strings comprising a plurality of parallel line-shaped active regions, a plurality of ferroelectric patterns disposed on the line-shaped active regions, and a plurality of word lines extending in parallel transversely across the active regions and disposed on the ferroelectric patterns.

2. The memory device of claim 1, further comprising a string select gate line extending transversely across the active regions in parallel with the word lines.

3. The memory device of claim 1, further comprising a ground select gate line extending transversely across the active regions in parallel with the word lines.

4. The memory device of claim 1, wherein the layer of parallel strings comprises first and second overlapping layers of parallel strings comprising respective first and second layers of parallel line-shaped active regions and respective first and second pluralities of word lines extending in parallel across respective ones of the first and second layers of active regions and disposed on ferroelectric patterns on the active regions, and wherein the memory device further comprises respective first and second layer select lines extending across respective ones of the first and second layers of active regions in parallel with the respective first and second pluralities of word lines.

5. The memory device of claim 4, further comprising a string select gate line extending transversely across one of the layers of active regions in parallel with the word lines thereon.

6. The memory device of claim 4, further comprising a ground select gate line extending transversely across one of the layers of active regions in parallel with the word lines thereon.

7. A memory device, comprising:
a semiconductor substrate;
an isolation layer defining a line-shaped active region in the semiconductor substrate;
a string select gate and a ground select gate spaced apart on the substrate and extending across the active region;
a ferroelectric pattern on the active region between the string select gate and the ground select gate; and
a word line on the ferroelectric pattern and extending across the active region between the string select gate and the ground select gate.

8. The memory device of claim 7, further comprising source/drain regions disposed in the active region between adjacent ones of the string select gate, the word line and the ground select gate.

9. The memory device of claim 8, wherein the line-shaped active region comprises a line-shaped well disposed therein having a first conductivity type and wherein the source/drain regions are disposed in the line-shaped well and have a second conductivity type.

10. The memory device of claim 7:
wherein the string select gate comprises:
a string select gate insulating layer on the active region; and
a string select gate electrode on the string gate insulating layer; and
wherein the ground select gate comprises:
a ground select gate insulating layer on the active region; and
a ground select gate electrode on the ground select gate insulating layer.

11. The memory device of claim 10, wherein the string select gate electrode and the ground select gate electrode comprise polysilicon patterns and/or stacks comprising polysilicon pattern and a metal silicide, and wherein the gate insulating layer comprises a silicon oxide layer and/or a high-k dielectric layer.

12. The memory device of claim 10, wherein the string select gate electrode and the ground select gate electrode and the word line include the same material, and wherein the string select gate insulating layer, the ground select gate insulating layer and the ferroelectric pattern include the same material.

13. The memory device of claim 7, wherein the ferroelectric pattern comprises a lead zirconate titanate layer (PbZrₓTi₁₋ₓO₃; PZT), a bismuth lanthanum titanate layer (Bi₄₋ₓLaₓTi₃O₁₂; BLT), a strontium bismuth tantalite layer (SrBi₂Ta₂O₅; SBT) and/or a lead germanium oxide layer (Pb₅Ge₅O₁₁; PGO).

14. The memory device of claim 7, wherein the word line comprises platinum (Pt), ruthenium (Ru), iridium (Ir) and/or iridium oxide (IrO₂).

15. The memory device of claim 7, further comprising an interfacial insulating layer pattern or a stack including an interfacial insulating layer pattern and a lower electrode interposed between the active region and the ferroelectric pattern.

16. The memory device of claim 7, wherein the word line comprises a first word line and wherein the memory device further comprises:
a lower interlayer insulating layer on the first word line;
a source line extending through the lower interlayer insulating layer to contact the active region on a side of the ground select gate opposite the word line;
an upper interlayer insulating layer covering the source line and the lower interlayer insulating layer; and
a bit line extending through the upper and lower interlayer insulating layers to contact the active region on a side of the string select gate electrode opposite the word line.

17. The memory device of claim 7, wherein the ferroelectric patterns comprise first ferroelectric patterns, wherein the word line comprises a first word line, and wherein the memory device further comprises:
a first layer select gate on the substrate and crossing the active region between the string select gate and the ground select gate;
an interlayer insulating layer covering the string select gate, the first word lines, the first layer select gate and the ground select gate;
a line-shaped semiconductor body pattern on the interlayer insulating layer and extending parallel to the active region;
a first contact plug extending through the line-shaped semiconductor body pattern and the interlayer insulating layer to contact the active region between the ground select gate and the first word line;
a second contact plug extending through the line-shaped semiconductor body pattern and the interlayer insulating layer to contact the active region between the string select gate and the first word line;
a second layer select gate extending across the line-shaped semiconductor body pattern between the first and second contact plugs;
a second ferroelectric pattern on the line-shaped semiconductor body pattern between the first and second contact plugs; and
a second word line on the second ferroelectric pattern and extending across the semiconductor body pattern between the first and second contact plugs.

18. The memory device of claim 17, wherein the first and second word lines comprise the same material, and wherein the first and second ferroelectric patterns comprise the same material.

19. The memory device of claim 17, wherein the first and second layer select gates each comprise a ferroelectric pattern and a gate electrode thereon.

20. The memory device of claim 17, further comprising second source/drain regions disposed in the semiconductor body pattern adjacent the second layer select gate and the second word line.

21. The memory device of claim 20, further comprising an impurity well in the semiconductor body pattern and having a first conductivity type, and wherein the second source/drain regions have a second conductivity type.

22. A memory device, comprising:
a semiconductor substrate;
an isolation region defining a plurality of line-shaped active regions disposed in parallel in the semiconductor substrate;
respective ferroelectric patterns on respective ones of the active regions;
a word line extending transversely across the active regions and disposed on the ferroelectric patterns;
source/drain regions in the active regions on respective first and second sides of the word line;
a common source line on the substrate and connected to the source/drain regions on the first side of the word line; and
respective bit lines on the substrate and connected to respective ones of the source/drain regions on the second side of the word line.

23. The memory device of claim 22, further comprising respective line-shaped wells in respective ones of the line-shaped active regions, and wherein the source/drain regions are disposed in the line-shaped wells.

24. The memory device of claim 22, wherein the ferroelectric patterns comprise a lead zirconate titanate layer (PbZrₓTi₁₋ₓO₃; PZT), a bismuth lanthanum titanate layer (Bi₄₋ₓLaₓTi₃O₁₂; BLT), a strontium bismuth tantalite layer (SrBi₂Ta₂O₅; SBT) and/or a lead germanium oxide layer (Pb₅Ge₅O₁₁; PGO).

25. The memory device of claim 22, wherein the word line comprises platinum (Pt), ruthenium (Ru), iridium (Ir) and/or iridium oxide (IrO₂).

26. The memory device of claim 22, further comprising respective interfacial insulating layer patterns or respective stacks including an interfacial insulating layer pattern and a lower electrode interposed between the active regions and the respective ferroelectric patterns.

27. The memory device of claim 22, wherein the ferroelectric patterns comprise first ferroelectric patterns, wherein the word line comprises a first word line, wherein the common source line comprises a first common source line, wherein the bit lines comprise first bit lines, and wherein the memory device further comprises:
a layer isolation insulating layer on the first bit lines;
a plurality of line-shaped semiconductor body patterns on the layer isolation layer insulating layer and extending parallel to the line-shaped active regions;
second ferroelectric patterns on the semiconductor body patterns;
a second word line extending transversely across the semiconductor body patterns parallel to the first word line and disposed on the second ferroelectric patterns;
second source/drain regions in the semiconductor body patterns on respective first and second sides of the second word line;
a second common source line on the substrate and electrically connected to the second source/drain regions on the first side of the second word line; and
a second plurality of bit lines on the substrate and electrically connected to the second source/drain regions on the second side of the second word line.

28. The memory device of claim 27, further comprising respective impurity wells in respective ones of the semiconductor body patterns and having a first conductivity type, and wherein the second source/drain regions are disposed in the impurity wells and have a second conductivity type.

29. The memory device of claim 22:
wherein the ferroelectric patterns comprises respective pluralities of spaced-apart ferroelectric patterns on respective ones of the active regions;
wherein the word line comprises a plurality of parallel word lines extending across the plurality of active regions and disposed on the ferroelectric patterns; and
wherein the memory device further comprises:
respective string select gates on respective ones of the plurality of active regions on a first side of the word line; and
respective ground select gates on respective ones of the plurality of active regions on a second side of the word line.

30. The memory device of claim 22:
wherein the ferroelectric patterns comprises respective pluralities of spaced-apart ferroelectric patterns on respective ones of the active regions;
wherein the word line comprises first and second parallel word lines extending across the plurality of active regions and disposed on the ferroelectric patterns; and
wherein the common source line is disposed between the first and second word lines and extends parallel thereto.

31. A method of fabricating a memory device, comprising:
forming an isolation region defining a line-shaped active region;
forming a string select gate structure, a ground select gate structure and a word line structure extending in parallel across the active region, the word line structure disposed between the string select gate structure and the ground select gate structure and comprising a ferroelectric pattern on the active region and a word line on the ferroelectric pattern;
forming a source line contacting the active region on a side of the ground select gate structure opposite the word line structure; and
forming a bit line contacting the active region on a side of the string select gate structure opposite the word line structure.

32. The method of claim 31, wherein forming a select gate structure, a ground select gate structure and a word line structure extending in parallel across the active region comprises:
forming the word line gate structure on the substrate;
forming a protective pattern covering the first cell gate;
sequentially forming a gate insulating layer and a gate electrode layer on the substrate; and
patterning the gate electrode layer and the gate insulating layer and forming the string select gate structure and the ground select gate structure.

33. The method of claim 32, wherein the gate insulating layer comprises a silicon oxide layer or a high-k dielectric layer, and the gate electrode layer comprises a polysilicon layer and/or a stack including a polysilicon layer and a metal silicide layer.

34. The method of claim 31, wherein the string select gate structure, the ground select gate structure and the word line structure have the same stacked structure.

35. The method of claim 31, wherein the word line structure comprises an interfacial insulating layer pattern or an interfacial insulating layer pattern and a lower electrode interposed between the active region and the ferroelectric pattern.

36. The method of claim 31, further comprising forming source/drain regions in the active region using the string select gate structure, the ground select gate structure, and the word line structure as ion implantation masks.

37. The method of claim 36:
wherein forming a source line comprises:
forming a lower interlayer insulating layer covering the string select gate structure, the ground select gate structure, and the word line structure; and
forming a source line extending through the lower interlayer insulating layer to contact the active region on a side of the ground select gate structure opposite the word line structure; and
wherein forming a bit line comprises:
forming an upper interlayer insulating layer on the source line and the lower interlayer insulating layer; and
forming a bit line on the upper insulation layer and extending through the upper and lower interlayer insulating layers to contact the active region on a side of string select gate structure opposite the word line.

38. The method of claim 37, further comprising forming a layer select gate structure on the active region between the ground select gate structure and the word line structure concurrent with forming the string select gate structure and the ground select gate structure.

39. The method of claim 38, wherein the word line structure comprises a first word line structure, wherein the layer select gate structure comprises a first layer select gate structure, wherein the source/drain regions comprise first source/drain regions, and wherein the method further comprises:
prior to the formation of the upper interlayer insulating layer, forming a line-shaped semiconductor body pattern on the lower interlayer insulating layer and extending parallel to the line-shaped active region;
forming a second word line structure and a second layer select gate structure extending across the semiconductor body pattern parallel to the first word line structure;
forming second source/drain regions in the semiconductor body pattern using the second word line structure and the second layer select gate structure as ion implantation masks; and
forming first and second contact plugs penetrating the lower interlayer insulating layer and electrically connecting the first source/drain regions between the ground select gate structure and the first layer select gate structure and between the string select gate structure and the first world line structure with respective ones of the second source/drain regions, wherein the second layer select gate structure is formed between the first contact plug and the second word line structure.

40. The method of claim 39, wherein the ferroelectric pattern comprises a first ferroelectric pattern, wherein the word line comprises a first word line, and wherein the second word line structure comprises a second ferroelectric pattern and a second word line thereon.

41. The method of claim 39, further comprising, after the formation of the semiconductor body pattern, forming an impurity well having a first conductivity type, and wherein forming second source/drain regions comprises forming the second source/drain regions with a second conductivity type in the semiconductor body pattern.

42. The method of claim 39, wherein forming the line-shaped semiconductor body pattern comprises:
forming a contact hole penetrating the lower interlayer insulating layer and exposing the active region between the string select gate and the first word line structure;
forming a single crystalline contact plug in the contact holes using a single crystalline growth process;
forming a non-single crystalline semiconductor layer covering the single crystalline contact plug on the lower interlayer insulating layer;
forming the non-single crystalline semiconductor layer into a single crystalline semiconductor layer using a solid phase epitaxy process; and
patterning the single crystalline semiconductor layer to form the semiconductor body pattern.

43. A method of fabricating a memory device, comprising:
forming an isolation layer defining a plurality of line-shaped active regions disposed in parallel in a semiconductor substrate;
forming a word line structure on the substrate crossing the active regions, the word line structures comprising respective ferroelectric patterns on the active regions and a word line on the ferroelectric patterns;
implanting impurity ions into the active regions using the word line structure as an ion implantation mask to form source/drain regions in the active regions;
forming a common source line one the substrate electrically connecting the first source regions on a first side of the word line structure; and
forming respective bit lines on the substrate and connected to respective ones of the source/drain regions on the second side of the word line structure.

44. The method of claim 43, comprising:
prior to forming the source/drain regions, forming respective line-shaped wells within the line-shaped active regions; and
forming the source/drain regions in the line-shaped wells.

45. The method of claim 43, wherein the common source line extends parallel to the word line gate structure or parallel to the active regions.

46. The method of claim 43, wherein the word line structure comprises respective interfacial insulating layer patterns or respective stacks including an interfacial insulating layer pattern and a lower electrode interposed between the active regions and the respective ferroelectric patterns.

47. The method of claim 43, wherein the word line structure comprises a first word line structure, wherein the common source line comprises a first common source line, wherein the bit lines comprise first bit lines, and wherein the method further comprises:
forming a layer isolation insulating layer covering the first word line structure;
forming a plurality of line-shaped semiconductor body patterns parallel to the line-shaped active regions on the layer isolation insulating layer;
forming a second word line structure crossing the semiconductor body patterns parallel to the first word line structure;
implanting impurity ions into the semiconductor body patterns using the second word line structure as an ion implantation mask to form second source/drain regions in the semiconductor body patterns on respective first and second sides of the second word line structure;
forming a second common source line electrically connecting the second source/drain regions on the first side of the second word line structure;
forming an upper interlayer insulating layer covering the second common source line; and
forming second bit lines on the upper interlayer insulating layer and extending therethrough to contact respective ones of the second source/drain regions on the second side of the second word line structure.

48. The method of claim 47, wherein the second word line structure comprises respective second ferroelectric patterns on respective ones of the semiconductor body patterns and a second word line on the second ferroelectric patterns.

49. The method of claim 47, further comprising, after the formation of the semiconductor body patterns, forming respective impurity wells having a first conductivity type in respective ones of the semiconductor body patterns, and wherein the second source/drain regions are disposed in the impurity wells.

50. The method of claim 47, wherein forming the line-shaped semiconductor body patterns comprises:
forming contact holes exposing the active regions through the layer isolation insulating layer and the lower interlayer insulating layer;
forming single crystalline contact plugs within the contact holes using a single crystalline growth process;
forming a non-single crystalline semiconductor layer covering the single crystalline contact plugs on the layer isolation insulating layer;
forming the non-single crystalline semiconductor layer into a single crystalline semiconductor layer using a solid phase epitaxy process; and
patterning the single crystalline semiconductor layer to form the semiconductor body patterns.

51. A write method for a memory device comprising a plurality of parallel line-shaped semiconductor wells and a plurality of ferroelectric word line structures comprising parallel word lines extending across the line-shaped wells and disposed on respective ferroelectric patterns, the method comprising:
simultaneously applying a first voltage to a selected well, floating others of the wells, applying a second voltage to a selected word line, and floating others of the word lines to polarize one of the ferroelectric patterns interposed between the selected word line and the selected well.

52. The write method of claim 51, wherein the memory device comprises source/drain regions in the wells adjacent the word line structures, and wherein simultaneously applying a first voltage to a selected well, floating others of the wells, applying a second voltage to a selected word line, and floating others of the word lines to polarize one of the ferroelectric patterns interposed between the selected word line and the selected well comprises simultaneously applying the first voltage to the selected well, floating the others of the wells, applying the second voltage to the selected word line, floating the others of the word lines and floating or grounding the source/drain regions to polarize the one of the ferroelectric patterns interposed between the selected word line and the selected well.

53. The write method of claim 51, wherein the first voltage is a ground voltage and the second voltage is a voltage greater than the first voltage.

54. The write method of claim 51, wherein the first voltage is a ground voltage and the second voltage is a voltage lower than the first voltage.

55. A read method for a memory device comprising a plurality of parallel line-shaped semiconductor wells, a plurality of ferroelectric word line structures comprising parallel word lines extending across the line-shaped wells and disposed on ferroelectric patterns on the line-shaped wells, and source/drain regions disposed in the wells between the word line structures, the method comprising:
while simultaneously grounding a selected well, floating or grounding a selected word line and applying a pass voltage to others of the word lines, determining a current passing through a channel controlled by the selected word line.

56. The read method of claim 55, wherein the memory device comprises first and second stacked layers of parallel line-shaped wells connected such that a respective well from the first layer is paralleled with a respective well from the second layer, respective first and second pluralities of word line structures comprising parallel word lines extending across respective ones of the first and second layers of parallel line-shaped wells and disposed on ferroelectric patterns on the wells, respective string select gates on one of the first and second wells and configured to couple respective paralleled wells from the first and second layers to respective bit lines, respective ground select gates on of the first and second wells and configured to couple respective parallels wells from the first and second layers to a source line, and respective first and second layer select gates extending across respective ones of the first and second layers of wells, and wherein while simultaneously grounding a selected well, floating or grounding a selected word line and applying a pass voltage to others of the word lines, determining a current passing through a channel controlled by the selected word line comprises:
while simultaneously grounding a selected well from the first and second layers of wells, applying a turn-on voltage to a string select gate and a ground select gate associated with the selected well, applying a turn-on voltage to a selected one of the first and second layer select gates, and floating or grounding a selected word line and applying the pass voltage to others of the word lines, determining a current passing through a channel in the selected well controlled by the selected word line.

57. A read method of a memory device comprising a plurality of parallel line-shaped semiconductor wells, a plurality of ferroelectric word line structures comprising parallel word lines extending across the line-shaped wells and disposed on ferroelectric patterns on the line-shaped wells, and source/drain regions disposed in the wells adjacent the word line structures, the method comprising:
while simultaneously grounding a selected well, floating or grounding a selected word line, applying an off voltage to non-selected word lines and applying a read voltage to a source/drain region adjacent the selected word line, determining a current flowing through a channel controlled by the selected word line.
